(19) United States
(12) Patent Application Publication
(10) Pub. No.: US 2024/0322002 A1
(43) Pub. Date: Sep. 26, 2024

(54) HETEROGENEOUS HETEROJUNCTION BIPOLAR TRANSISTOR DEVICES AND METHODS OF MAKING AND USE THEREOF

(71) Applicant: North Carolina State University, Raleigh, NC (US)

(72) Inventors: Spyridon Pavlidis, Raleigh, NC (US); Fred Kish, Raleigh, NC (US)

(21) Appl. No.: 18/418,410

(22) Filed: Jan. 22, 2024

Related U.S. Application Data
(60) Provisional application No. 63/453,828, filed on Mar. 22, 2023.

(51) Int. Cl. H01L 29/66; H01L 21/18; H01L 29/20; H01L 29/205; H01L 29/737

(52) U.S. Cl. CPC H01L 29/66318; H01L 21/187; H01L 29/2003; H01L 29/205; H01L 29/7378

(57) ABSTRACT

Disclosed herein are heterojunction bipolar transistor (HBT) devices and methods of making and use thereof.

### CROSS-REFERENCE TO RELATED APPLICATIONS

This application claims the benefit of priority to U.S. Provisional Application No. 63/453,828 filed Mar. 22, 2023, which is hereby incorporated herein by reference in its entirety.

### STATEMENT OF GOVERNMENT SUPPORT

This invention was made with government support under grant number HR0011-21-9-0106 awarded by the Defense Advanced Research Projects Agency. The government has certain rights in the invention.

### BACKGROUND

The high-power performance limit of heterojunction bipolar transistors (HBT's) is dictated by the intrinsic and extrinsic properties of the base and collector regions. In the base, transport properties, doping limits, and the ability to form low resistance contacts are important. In the collector, the ability to withstand large electric fields and achieve high saturation velocities are paramount. Traditional compound semiconductors, such as arsenic- and phosphide-based III-V's, offer high-speed performance facilitated by high mobilities and doping limits, but their output power can be limited due to their narrow bandgap. In contrast, wide bandgap semiconductors, such as those based on III-N's, can offer large critical electric fields and saturation velocities, but can be hampered by lower doping and mobilities. Thus, there is a need to address the limitations of the semiconductor layers used in HBT's in order to improve their high-power performance. The methods and devices discussed herein address these and other needs.

### SUMMARY

In accordance with the purposes of the disclosed methods and devices as embodied and broadly described herein, the disclosed subject matter relates to heterojunction bipolar transistor (HBT) devices and methods of making and use thereof. Additional advantages of the disclosed devices and methods will be set forth in part in the description which follows, and in part will be obvious from the description. The advantages of the disclosed devices and methods will be realized and attained by means of the elements and combinations particularly pointed out in the appended claims. It is to be understood that both the foregoing general description and the following detailed description are exemplary and explanatory only and are not restrictive of the disclosed devices and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure, and together with the description, serve to explain the principles of the disclosure. However, the present disclosure is not limited to the precise arrangements shown, and the drawings are not necessarily drawn to scale.

FIG. 1 is a schematic cross-sectional view of an example method of making an example heterojunction bipolar transistor (HBT) device as disclosed herein according to one implementation.

FIG. 2 is a schematic cross-sectional view of the semiconductor layers of an example heterojunction bipolar transistor (HBT) device as disclosed herein according to one implementation.

FIG. 3 is a schematic cross-sectional view of an example method of making an example heterojunction bipolar transistor (HBT) device as disclosed herein according to one implementation.

FIG. 4 is a schematic cross-sectional view of an example method of making an example heterojunction bipolar transistor (HBT) device as disclosed herein according one implementation.

FIG. 5 is a schematic cross-sectional view of an example method of making an example heterojunction bipolar transistor (HBT) device as disclosed herein according to one implementation.

FIG. 6 is a schematic cross-sectional view of the semiconductor layers of an example heterojunction bipolar transistor (HBT) device as disclosed herein according to one implementation.

FIG. 7 is a schematic cross-sectional view of the semiconductor layers of an example heterojunction bipolar transistor (HBT) device as disclosed herein according to one implementation.

FIG. 8 is a schematic cross-sectional view of an example heterojunction bipolar transistor (HBT) device as disclosed herein according to one implementation.

FIG. 9 is a schematic cross-sectional view of an example heterojunction bipolar transistor (HBT) device as disclosed herein according to one implementation.

FIG. 10 is a schematic cross-sectional view of an example heterojunction bipolar transistor (HBT) device as disclosed herein according to one implementation.

FIG. 11 is an image of a GaAs substrate bonded to a free-standing GaN substrate. The large lattice mismatch results in large non-bonded areas and generally weaker bonds.

FIG. 12 is an image of an InP substrate wafer bonded to a free-standing GaN substrate that shows ˜100% bonded area and a strong, robust bonded interface. The arc in the upper right corner does not represent a defect, it is present because one of the edges of the sample is rounded prior to wafer bonding.

FIG. 13 is a schematic cross-sectional view of an example heterojunction bipolar transistor (HBT) device as disclosed herein. The device includes a heterogeneous heterojunction (HH) formed at a p⁺-GaAs base with an n⁺-In_{0.5}Ga_{0.5}P emitter (lattice-matched to GaAs) above.

FIG. 14 is a schematic cross-sectional view of an example heterojunction bipolar transistor (HBT) device as disclosed herein. The device includes a heterogeneous heterojunction (HH) formed at a p⁺-In_{0.5}Ga_{0.47}As base with an N⁺-InP emitter (lattice matched to InP) above.

### DETAILED DESCRIPTION

The methods and devices described herein may be understood more readily by reference to the following detailed description of specific aspects of the disclosed subject matter and the Examples included therein.

Before the present methods and devices are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

### General Definitions

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Values can be expressed herein as an “average” value. “Average” generally refers to the statistical mean value.

By “substantially” is meant within 10%, e.g., within 9%, 8%, 7%, 6%, 5%, 4%, 3%, 2%, or 1%.

“Exemplary” means “an example of” and is not intended to convey an indication of a preferred or ideal embodiment. “Such as” is not used in a restrictive sense, but for explanatory purposes.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

### Methods and Devices

Disclosed herein are heterojunction bipolar transistor (HBT) devices and methods of making and use thereof.

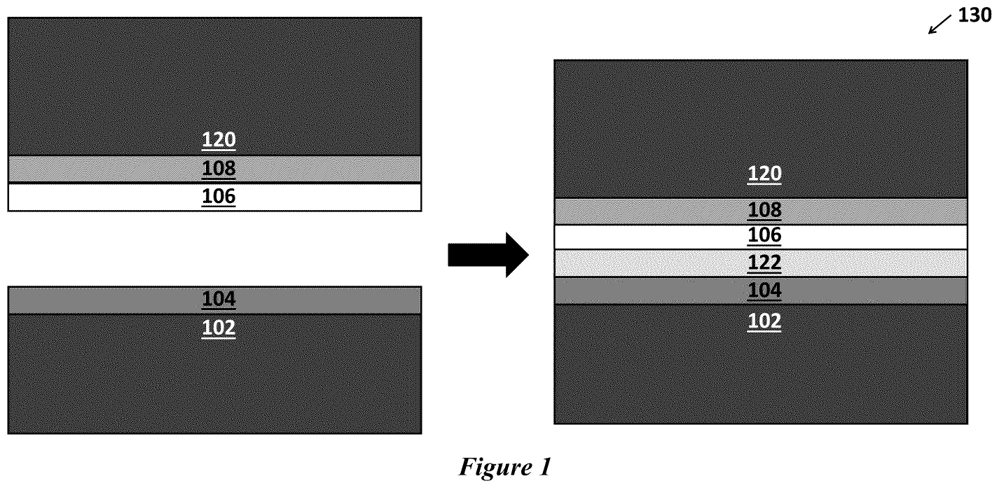

Referring now to FIG. 1, disclosed herein are methods of making a heterogeneous heterojunction bipolar transistor (HBT) device 100, the methods comprising depositing a collector layer 104 (e.g., one or more collector layers) on a first substrate 102. The methods further comprise depositing an emitter layer 108 (e.g., one or more emitter layers) on a second substrate 120 and subsequently depositing a base layer 106 (e.g., one or more base layers) on the emitter layer 108.

Depositing the collector layer 104, the emitter layer 108, and the base layer 106 can independently comprise any suitable method, such as, for example, metal organic chemical vapor deposition (MOCVD), molecular-beam epitaxy (MBE), hydride vapor phase epitaxy (HVPE), pulsed laser deposition (PLD), low pressure chemical vapor deposition (LPCVD), metal-organic chemical beam epitaxy (MOMBE), vapor phase epitaxy (VPE), liquid phase epitaxy (LPE), similar techniques that produce crystalline epitaxial layers, or a combination thereof. In some examples, depositing the collector layer 104, the emitter layer 108, and the base layer 106 can independently comprise metal organic chemical vapor deposition (MOCVD) and/or molecular-beam epitaxy (MBE). The methods further comprise fusing the base layer 106 to the collector layer 104 using crystal heterogeneous integration wafer bonding, thereby forming an interface 122 that fuses the base layer 106 to the collector layer 104 and thus forming a precursor device 130.

Fusing the base layer 106 to the collector layer 104 using crystal heterogeneous integration wafer bonding can, for example, comprise contacting the base layer 106 with the collector layer 104 at an elevated temperature (e.g., 400-1000° C.) and at an elevated pressure (e.g., 1 MPa-100 MPa) in an environment with an overpressure of a gas comprising a group V element or compound. In some examples, the environment can further include an inert gas, such as He, N₂, Ar, or a combination thereof. In some examples, the environment can further include an atmosphere to remove surface oxides and/or enhance mass transport and solid-state regrowth, such as H₂.

For example, the elevated temperature can be 400° C. or more (e.g., 425° C. or more, 450° C. or more, 475° C. or more, 500° C. or more, 525° C. or more, 550° C. or more, 575° C. or more, 600° C. or more, 625° C. or more, 650° C. or more, 675° C. or more, 700° C. or more, 725° C. or more, 750° C. or more, 775° C. or more, 800° C. or more, 825° C. or more, 850° C. or more, 875° C. or more, 900° C. or more, 925° C. or more, 950° C. or more). In some examples, the elevated temperature can be 1000° C. or less (e.g., 975° C. or less, 950° C. or less, 925° C. or less, 900° C. or less, 875° C. or less, 850° C. or less, 825° C. or less, 800° C. or less, 775° C. or less, 750° C. or less, 725° C. or less, 700° C. or less, 675° C. or less, 650° C. or less, 625° C. or less, 600° C. or less, 575° C. or less, 550° C. or less, 525° C. or less, 500° C. or less, 475° C. or less, or 450° C. or less). The elevated temperature can range from any of the minimum values described above to any of the maximum values described above. For example, the elevated temperature can be from 400° C. to 1000° C. (e.g., from 400° C. to 700° C., from 700° C. to 1000° C., from 400° C. to 500° C., from 500° C. to 600° C., from 600° C. to 700° C., from 700° C. to 800° C., from 800° C. to 900° C., from 900° C. to 1000° C., from 400° C. to 900° C., from 400° C. to 800° C., from 400° C. to 600° C., from 500° C. to 1000° C., from 600° C. to 1000° C., from 800° C. to 1000° C., from 450° C. to 950° C., or from 500° C. to 900° C.).

For example, the elevated pressure can be 1 MPa or more (e.g., 5 MPa or more, 10 MPa or more, 15 MPa or more, 20 MPa or more, 25 MPa or more, 30 MPa or more, 35 MPa or more, 40 MPa or more, 45 MPa or more, 50 MPa or more, 55 MPa or more, 60 MPa or more, 65 MPa or more, 70 MPa or more, 75 MPa or more, 80 MPa or more, 85 MPa or more, or 90 MPa or more). In some examples, the elevated pressure can be 100 MPa or less (e.g., 95 MPa or less, 90 MPa or less, 85 MPa or less, 80 MPa or less, 75 MPa or less, 70 MPa or less, 65 MPa or less, 60 MPa or less, 55 MPa or less, 50 MPa or less, 45 MPa or less, 40 MPa or less, 35 MPa or less, 30 MPa or less, 25 MPa or less, 20 MPa or less, 15 MPa or less, or 10 MPa or less). The elevated pressure can range from any of the minimum values described above to any of the maximum values described above. For example, the elevated pressure can be from 1 to 100 MPa (e.g., from 1 to 50 MPa, from 50 to 100 MPa, from 1 to 20 MPa, from 20 to 40 MPa, from 40 to 60 MPa, from 60 to 80 MPa, from 80 to 100 MPa, from 1 to 90 MPa, from 1 to 80 MPa, from 1 to 70 MPa, from 1 to 60 MPa, from 1 to 40 MPa, from 1 to 30 MPa, from 1 to 10 MPa, from 5 to 100 MPa, from 10 to 100 MPa, from 20 to 100 MPa, from 30 to 100 MPa, from 40 to 100 MPa, from 60 to 100 MPa, from 70 to 100 MPa, from 90 to 100 MPa, from 5 to 95 MPa, or from 10 to 90 MPa).

As used herein, group V of the periodic table includes N, P, As, Sb, and Bi. In some examples, the group V compound comprises a nitrogen compound, a phosphorous compound, an arsenic compound, or a combination thereof. In some examples, the gas comprising the group V element or compound comprises NH₃, tertiarybutylarsine (TBAs), AsH₃, PH₃, SbH₃, tertiarybutylphosphine (TBP), tertiary-butylhydrazine, diemthylhyrdarzine (UDMHy), diethylgallium amide, trimethylantimony (TMSb), tris(dimethylamino) antimony (AMSb), other metalorganic chemical molecules comprising a group V element as described by G.B. Stringfellow (Organometallic Vapor-Phase Epitaxy: Theory and Practice, Second Edition, Academic Press, Boston, 1999, especially Table 2.6), or a combination thereof.

The identity of the gas comprising the group V element or compound can be selected in view of a variety of features. For example, the identity of the gas comprising the group V element or compound can be selected based on the composition of the various layers. In some examples, the identity of the gas comprising the group V element or compound can be selected based on the most volatile III-V compound at the interface. In some examples, the identity of the gas comprising the group V element or compound can be selected to include that of the column V compound of all exposed surfaces. For example, for an InGaAs—GaN HH, As would be the most volatile species, but a N atmosphere could also be provided. Similarly, as when InGaAs is grown on InP, a P environment can also be provided.

Fusing the base layer 106 to the collector layer 104 using crystal heterogeneous integration wafer bonding can, for example, further comprise subsequently applying a uniaxial force (e.g., 1-100 MPa) to the first substrate and/or the second substrate for an amount of time (e.g., from 1 second to 24 hours), and optionally at an elevated temperature (e.g., 400-1000° C.), wherein the force is applied in a direction that is substantially perpendicular to a plane substantially parallel with the first substrate and/or the second substrate.

For example, the uniaxial force can be 1 MPa or more (e.g., 5 MPa or more, 10 MPa or more, 15 MPa or more, 20 MPa or more, 25 MPa or more, 30 MPa or more, 35 MPa or more, 40 MPa or more, 45 MPa or more, 50 MPa or more, 55 MPa or more, 60 MPa or more, 65 MPa or more, 70 MPa or more, 75 MPa or more, 80 MPa or more, 85 MPa or more, or 90 MPa or more). In some examples, the uniaxial force can be 100 MPa or less (e.g., 95 MPa or less, 90 MPa or less, 85 MPa or less, 80 MPa or less, 75 MPa or less, 70 MPa or less, 65 MPa or less, 60 MPa or less, 55 MPa or less, 50 MPa or less, 45 MPa or less, 40 MPa or less, 35 MPa or less, 30 MPa or less, 25 MPa or less, 20 MPa or less, 15 MPa or less, or 10 MPa or less). The uniaxial force can range from any of the minimum values described above to any of the maximum values described above. For example, the uniaxial force can be from 1 to 100 MPa (e.g., from 1 to 50 MPa, from 50 to 100 MPa, from 1 to 20 MPa, from 20 to 40 MPa, from 40 to 60 MPa, from 60 to 80 MPa, from 80 to 100 MPa, from 1 to 90 MPa, from 1 to 80 MPa, from 1 to 70 MPa, from 1 to 60 MPa, from 1 to 40 MPa, from 1 to 30 MPa, from 1 to 10 MPa, from 5 to 100 MPa, from 10 to 100 MPa, from 20 to 100 MPa, from 30 to 100 MPa, from 40 to 100 MPa, from 60 to 100 MPa, from 70 to 100 MPa, from 90 to 100 MPa, from 5 to 95 MPa, or from 10 to 90 MPa).

For example, the amount of time can be 1 second or more (e.g., 5 seconds or more, 10 seconds or more, 15 seconds or more, 20 seconds or more, 25 seconds or more, 30 seconds or more, 35 seconds or more, 40 seconds or more, 45 seconds or more, 50 seconds or more, 55 seconds or more, 1 minute or more, 5 minutes or more, 10 minutes or more, 15 minutes or more, 20 minutes or more, 25 minutes or more, 30 minutes or more, 35 minutes or more, 40 minutes or more, 45 minutes or more, 50 minutes or more, 55 minutes or more, 1 hour or more, 2 hours or more, 3 hours or more, 4 hours or more, 5 hours or more, 6 hours or more, 7 hours or more, 8 hours or more, 9 hours or more, 10 hours or more, 11 hours or more, 12 hours or more, 14 hours or more, 16 hours or more, 18 hours or more, 20 hours or more, or 22 hours or more). In some examples, the amount of time can be 24 hours or less (e.g., 22 hours or less, 20 hours or less, 18 hours or less, 16 hours or less, 14 hours or less, 12 hours or less, 11 hours or less, 10 hours or less, 9 hours or less, 8 hours or less, 7 hours or less, 6 hours or less, 5 hours or less, 4 hours or less, 3 hours or less, 2 hours or less, 1 hour or less, 55 minutes or less, 50 minutes or less, 45 minutes or less, 40 minutes or less, 35 minutes or less, 30 minutes or less, 25 minutes or less, 20 minutes or less, 15 minutes or less, 10 minutes or less, 5 minutes or less, 1 minute or less, 55 seconds or less, 50 seconds or less, 45 seconds or less, 40 seconds or less, 35 seconds or less, 30 seconds or less, 25 seconds or less, 20 seconds or less, 15 seconds or less, 10 seconds or less, or 5 seconds or less). The amount of time can range from any of the minimum values described above to any of the maximum values described above. For example, the amount of time can be from 1 second to 24 hours (e.g., from 1 second to 6 hours, from 6 hours to 24 hours, from 1 second to 1 minute, from 1 minute to 1 hour, from 1 hour to 24 hours, from 1 second to 18 hours, from 1 second to 12 hours, from 30 seconds to 24 hours, from 1 minute to 24 hours, from 30 minutes to 24 hours, from 12 hours to 24 hours, from 1 minute to 22 hours, or from 10 minutes to 20 hours).

For example, the elevated temperature can be 400° C. or more (e.g., 425° C. or more, 450° C. or more, 475° C. or more, 500° C. or more, 525° C. or more, 550° C. or more, 575° C. or more, 600° C. or more, 625° C. or more, 650° C. or more, 675° C. or more, 700° C. or more, 725° C. or more, 750° C. or more, 775° C. or more, 800° C. or more, 825° C. or more, 850° C. or more, 875° C. or more, 900° C. or more, 925° C. or more, 950° C. or more). In some examples, the elevated temperature can be 1000° C. or less (e.g., 975° C. or less, 950° C. or less, 925° C. or less, 900° C. or less, 875° C. or less, 850° C. or less, 825° C. or less, 800° C. or less, 775° C. or less, 750° C. or less, 725° C. or less, 700° C. or less, 675° C. or less, 650° C. or less, 625° C. or less, 600° C. or less, 575° C. or less, 550° C. or less, 525° C. or less, 500° C. or less, 475° C. or less, or 450° C. or less). The elevated temperature can range from any of the minimum values described above to any of the maximum values described above. For example, the elevated temperature can be from 400° C. to 1000° C. (e.g., from 400° C. to 700° C., from 700° C. to 1000° C., from 400° C. to 500° C., from 500° C. to 600° C., from 600° C. to 700° C., from 700° C. to 800° C., from 800° C. to 900° C., from 900° C. to 1000° C., from 400° C. to 900° C., from 400° C. to 800° C., from 400° C. to 600° C., from 500° C. to 1000° C., from 600° C. to 1000° C., from 800° C. to 1000° C., from 450° C. to 950° C., or from 500° C. to 900° C.).

The precursor device 130 can, for example comprise: the first substrate 102, the collector layer 104, the interface 122, the base layer 106, the emitter layer 108, and the second substrate 120; wherein: the collector layer 104 is disposed on top of and in physical contact with the first substrate 102; the interface 122 is disposed on top of and in physical contact with the collector layer 104, such that the collector layer 104 is disposed between and in physical contact with the first substrate 102 and the interface 122; the base layer 106 is disposed on top of and in physical contact with the interface 122, such that the interface 122 is disposed between and in physical contact with the collector layer 104 and the base layer 106; the emitter layer 108 is disposed on top of and in physical contact with the base layer 106, such that the base layer 106 is disposed between and in physical contact with the interface 122 and the emitter layer 108; and the second substrate 120 is disposed on top of an in physical contact with the emitter layer 108, such that the emitter layer 108 is disposed between and in physical contact with the base layer 106 and the second substrate 120.

As used herein “in physical contact” includes situations where macro to atomic level defects are optionally present, though at a quantity such as to be able to make devices with sufficiently good performance and yield. Defect densities will be governed by both lattice-mismatch and process induced defects. Total defect density should be <10× the carrier density in the operating device.

The interface 122 can, for example, comprise the heterogeneous heterojunction (HH). The characteristic of the HH is defined herein as a layer that exhibits the properties that are characteristic of a layer that has undergone wafer bonding. It is believed that one such characteristic is a different nature of misfit dislocations formed at the wafer bonded interface, compared to an epitaxially grown mismatched heterointerface. An interface that has undergone wafer bonding has been observed to exhibit misfit dislocations which primarily consist of “edge dislocations,” i.e. dislocations whose Burgers vector lies in the plane of the wafer bonded interface. These properties are in contrast to an epitaxially grown mismatched interface, which typically exhibits a much higher density of “threading dislocations,” i.e. dislocations which are not confined to the plane of the mismatched interface and tend to propagate perpendicular to the interface.

The methods further comprise processing the precursor device 130 to remove the second substrate 120, thereby forming the heterogeneous heterojunction bipolar transistor (HBT) device 100. For example, the methods can further comprise etching the precursor device 130 to remove the second substrate 120. Etching the precursor device 130 can, for example comprise etching away the second substrate, a “lift-off” process where exposing the precursor device 130 to an etchant releases the second substrate, exposing the precursor device to an etchant to cleave at least a portion of the second substrate 120, or a combination thereof. In some examples, Etching the precursor device 130 can, for example, comprise exposing the precursor device 130 to an etchant for an amount of time. In some examples, the etchant can exhibit a selectivity of 10:1 or more towards the second substrate 120.

In some examples, etching the precursor device 130 can, for example, comprise exposing the precursor device 130 to an etchant that is selective towards the second substrate 120 but not the release layer 124, the collector layer 104, nor the first substrate 102. This can be accomplished using wet or plasma etching, or a combination of both, as long as the selectivity criteria are satisfied, and the resulting exposed surface of the collector layer 104 remains smooth. In some examples, an initial etch step can be used to remove the second substrate 120, stopping at the release layer 124. The initial etch process can be selective against release layer 124. This is followed by a second etch step to remove the release layer 124, and stop at the collector layer 104. The second etch process can be selective against the collector layer 104. In cases where sufficient etch selectivity exists between the collector layer 104 and the second substrate 120, the release layer 124 can be excluded and a single etch step can be executed. Sufficient etch selectivity is defined as 10:1 or larger towards the second substrate 120.

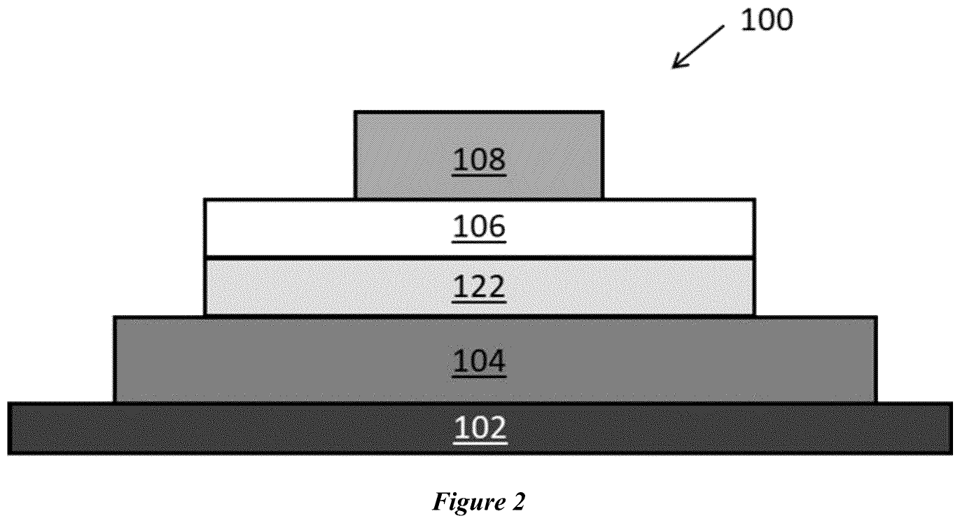

Referring now to FIG. 2, the heterogeneous heterojunction bipolar transistor (HBT) device 100 made by the methods disclosed herein can comprise: the first substrate 102, the collector layer 104, the interface 122, the base layer 106, and the emitter layer 108; wherein: the collector layer 104 is disposed on top of and in physical contact with the first substrate 102; the interface 122 is disposed on top of and in physical contact with the collector layer 104, such that the collector layer 104 is disposed between and in physical contact with the first substrate 102 and the interface 122; the base layer 106 is disposed on top of and in physical contact with the interface 122, such that the interface 122 is disposed between and in physical contact with the collector layer 104 and the base layer 106; and the emitter layer 108 is disposed on top of and in physical contact with the base layer 106, such that the base layer 106 is disposed between and in physical contact with the interface 122 and the emitter layer 108.

In some examples, homoepitaxy and/or heteroepitaxy can be used to deposit the collector layer 104 on the first substrate 102. In some examples, the collector layer 104 and the first substrate 102 comprise the same material, such as depositing a GaN thin film on a single-crystal bulk GaN substrate. In some examples, heteroepitaxy can be used to deposit the collector layer 104 on the first substrate 102, for example when the first substrate 102 and the collector layer 104 have a non-zero lattice mismatch. A relaxed collector layer 104 can, for example, be obtained via heteroepitaxy when appropriate. Further, nucleation and/or buffer layers can also be used, for example to realize higher quality epitaxial device layers.

In some examples, the first substrate 102 and the collector layer 104 have a lattice mismatch of 30% or less (e.g., 25% or less, 20% or less, 15% or less, 10% or less, 5% or less, or 1% or less). In some examples, the first substrate 102 and the collector layer 104 have a lattice mismatch of 0% or more (e.g., 1% or more, 5% or more, 10% or more, 15% or more, 20% or more, or 25% or more). The lattice mismatch between the first substrate 102 and the collector layer 104 can range from any of the minimum values described above to any of the maximum values described above. For example, the first substrate 102 and the collector layer 104 can have a lattice mismatch of from 0% to 30% (e.g., from 0% to 15%, from 15% to 30%, from 0% to 5%, from 5% to 10%, from 10% to 15%, from 15% to 20%, from 20% to 25%, from 25% to 30%, from 0% to 20%, from 0% to 10%, from 0% to 1%, from 1% to 30%, from 5% to 30%, from 10% to 30%, from 20% to 30%, from 1% to 25%, or from 5% to 20%). In some examples, the first substrate 102 and the collector layer 104 are lattice matched. In some examples, the collector layer 104 is pseudomorphically grown on the first substrate 102, for example wherein its strain is less than its critical thickness.

In some examples, the second substrate 120 and the emitter layer 108 have a lattice mismatch of 30% or less (e.g., 25% or less, 20% or less, 15% or less, 10% or less, 5% or less, or 1% or less). In some examples, the second substrate 120 and the emitter layer 108 have a lattice mismatch of 0% or more (e.g., 1% or more, 5% or more, 10% or more, 15% or more, 20% or more, or 25% or more). The lattice mismatch between the second substrate 120 and the emitter layer 108 can range from any of the minimum values described above to any of the maximum values described above. For example, the second substrate 120 and the emitter layer 108 can have a lattice mismatch of from 0% to 30% (e.g., from 0% to 15%, from 15% to 30%, from 0% to 5%, from 5% to 10%, from 10% to 15%, from 15% to 20%, from 20% to 25%, from 25% to 30%, from 0% to 20%, from 0% to 10%, from 0% to 1%, from 1% to 30%, from 5% to 30%, from 10% to 30%, from 20% to 30%, from 1% to 25%, or from 5% to 20%). In some examples, the second substrate 120 and the emitter layer 108 are lattice matched. In some examples, the emitter layer 108 is pseudomorphically grown on the second substrate 120.

In some examples, the base layer 106 and the emitter layer 108 have a lattice mismatch of 30% or less (e.g., 25% or less, 20% or less, 15% or less, 10% or less, 5% or less, or 1% or less). In some examples, the base layer 106 and the emitter layer 108 have a lattice mismatch of 0% or more (e.g., 1% or more, 5% or more, 10% or more, 15% or more, 20% or more, or 25% or more). The lattice mismatch between the base layer 106 and the emitter layer 108 can range from any of the minimum values described above to any of the maximum values described above. For example, the base layer 106 and the emitter layer 108 can have a lattice mismatch of from 0% to 30% (e.g., from 0% to 15%, from 15% to 30%, from 0% to 5%, from 5% to 10%, from 10% to 15%, from 15% to 20%, from 20% to 25%, from 25% to 30%, from 0% to 20%, from 0% to 10%, from 0% to 1%, from 1% to 30%, from 5% to 30%, from 10% to 30%, from 20% to 30%, from 1% to 25%, or from 5% to 20%). In some examples, the base layer 106 and the emitter layer 108 can be lattice matched. In some examples, the base layer 106 is pseudomorphically grown on the emitter layer 108. In some examples, the base layer 106 is lattice matched to the emitter layer 108 and the second substrate 120.

In some examples, the collector layer 104 has a first band gap, the emitter layer 108 has a second bandgap, and the base layer 106 has a third bandgap.

In some examples, the first bandgap (e.g., the bandgap of the collector layer 104) is greater than the third bandgap (e.g., the bandgap of the base layer 106).

In some examples, the second band gap (e.g., the bandgap of the emitter layer 108) is greater than the third bandgap (e.g., the bandgap of the base layer 106).

In some examples, the first substrate 102 has a first coefficient of thermal expansion; the collector layer 104 has a second coefficient of thermal expansion; the second substrate 120 has a third coefficient of thermal expansion; the emitter layer 108 has a fourth coefficient of thermal expansion; and the base layer 106 has a fifth coefficient of thermal expansion.

In some examples, the difference between the first coefficient of thermal expansion (e.g., the coefficient of thermal expansion of the first substrate 102) and the third coefficient of thermal expansion (e.g., the coefficient of thermal expansion of the second substrate 120) is 30% or less (e.g., 25% or less, 20% or less, 15% or less, 10% or less, 5% or less, 4% or less, 3% or less, 2% or less, or 1% or less). In some examples, the difference between the first coefficient of thermal expansion (e.g., the coefficient of thermal expansion of the first substrate 102) and the third coefficient of thermal expansion (e.g., the coefficient of thermal expansion of the second substrate 120) is 0% or more (e.g., 1% or more, 2% or more, 3% or more, 4% or more, 5% or more, 10% or more, 15% or more, 20% or more, or 25% or more). The difference between the first coefficient of thermal expansion (e.g., the coefficient of thermal expansion of the first substrate 102) and the third coefficient of thermal expansion (e.g., the coefficient of thermal expansion of the second substrate 120) can range from any of the minimum values described above to any of the maximum values described above. For example, the difference between the first coefficient of thermal expansion (e.g., the coefficient of thermal expansion of the first substrate 102) and the third coefficient of thermal expansion (e.g., the coefficient of thermal expansion of the second substrate 120) can be from 0% to 30% (e.g., from 0% to 15%, from 15% to 30%, from 0% to 5%, from 5% to 10%, from 10% to 15%, from 15% to 20%, from 20% to 25%, from 25% to 30%, from 0% to 20%, from 0% to 10%, from 0% to 1%, from 1% to 30%, from 5% to 30%, from 10% to 30%, from 20% to 30%, from 1% to 25%, or from 5% to 20%).

The ability to integrate the layers grown on the first substrate 102 and the second substrate 120 can be strongly influenced by the CTE mismatch between the first substrate 102 and the second substrate 120.

The first substrate 102 can comprise any suitable material. the first substrate 102 comprises Al_{w}Ga_{1-w}N where w is from 0 to 1 (e.g., AlN, AlGaN, GaN), Si, sapphire, SiC, any substrate that sufficient quality III-N epitaxial layers can be realized, or a combination thereof; In some examples, the first substrate 102 comprises Al_{w}Ga_{1-w}N where w is from 0 to 1. For example, w can be 0 or more (e.g., 0.1 or more, 0.2 or more, 0.3 or more, 0.4 or more, 0.5 or more, 0.6 or more, 0.7 or more, 0.8 or more, or 0.9 or more). In some examples, w can be 1 or less (e.g., 0.9 or less, 0.8 or less, 0.7 or less, 0.6 or less, 0.5 or less, 0.4 or less, 0.3 or less, 0.2 or less, or 0.1 or less). The value of w can range from any of the minimum values described above to any of the maximum values described above. For example, w can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.5, from 0 to 0.4, from 0 to 0.3, from 0 to 0.2, from 0 to 0.1, from 0.1 to 1, from 0.2 to 1, from 0.3 to 1, from 0.4 to 1, from 0.5 to 1, from 0.6 to 1, from 0.7 to 1, from 0.8 to 1, from 0.9 to 10, from 0.1 to 0.9, from 0.2 to 0.8, or from 0.3 to 0.7). In some examples, the first substrate 102 comprises GaN, AlN, or a combination thereof.

In some examples, the first substrate 102 is a low-dislocation material and/or a material with a large thermal conductivity.

The collector layer 104 can comprise any suitable material, such as a group III-nitride based material. As used herein, group III of the periodic table includes B, Al, Ga, In, and Tl. In some examples, the collector layer 104 comprises an n-type group III-nitride. In some examples, the collector layer 104 comprises a GaN-based material (e.g., a material comprising GaN).

In some examples, the collector layer 104 comprises AlₓGa₁₋ₓN, wherein x is from 0 to 1. For example, x can be 0 or more (e.g., 0.1 or more, 0.2 or more, 0.3 or more, 0.4 or more, 0.5 or more, 0.6 or more, 0.7 or more, 0.8 or more, or 0.9 or more). In some examples, x can be 1 or less (e.g., 0.9 or less, 0.8 or less, 0.7 or less, 0.6 or less, 0.5 or less, 0.4 or less, 0.3 or less, 0.2 or less, or 0.1 or less). The value of x can range from any of the minimum values described above to any of the maximum values described above. For example, x can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.5, from 0 to 0.4, from 0 to 0.3, from 0 to 0.2, from 0 to 0.1, from 0.1 to 1, from 0.2 to 1, from 0.3 to 1, from 0.4 to 1, from 0.5 to 1, from 0.6 to 1, from 0.7 to 1, from 0.8 to 1, from 0.9 to 10, from 0.1 to 0.9, from 0.2 to 0.8, or from 0.3 to 0.7).

In some examples of the methods and devices described herein, the collector layer 104 has a wider bandgap than the emitter layer 108 and the base layer 106. In some examples, the collector layer 104 has a wider bandgap than that which can be epitaxially grown in a single-step with the emitter layer 108 and the base layer 106 with sufficiently low defect density (e.g., a defect density of <5E6 cm⁻², preferably <1E5 cm⁻², most preferably <1E4 cm⁻²). In some examples, the first substrate 102 comprises GaN and the collector layer 104 comprises AlₓGa₁₋ₓN, wherein x is from 0 to 0.5, from 0 to 0.3, or from 0 to 0.15. In some examples, the first substrate 102 comprises AlN and the collector layer 104 comprises AlₓGa₁₋ₓN, wherein x is from 0.5 to 1, from 0.7 to 1, or from 0.85 to 1.

In some examples, the collector layer 104 comprises GaN, AlₓGa₁₋ₓN wherein x is from 0 to 0.3, or a combination thereof.

In some examples, the collector layer 104 comprises GaN, Al_{0.7}Ga_{0.3}N, or a combination thereof.

In some examples, the collector layer 104 has an average thickness of 100 nanometers (nm) or more (e.g., 110 nm or more, 120 nm or more, 130 nm or more, 140 nm or more, 150 nm or more, 175 nm or more, 200 nm or more, 225 nm or more, 250 nm or more, 275 nm or more, 300 nm or more, 350 nm or more, 400 nm or more, 450 nm or more, 500 nm or more, 550 nm or more, 600 nm or more, 650 nm or more, 700 nm or more, 750 nm or more, 800 nm or more, 850 nm or more, 900 nm or more, 950 nm or more, 1 micrometer (micron, μm) or more, 1.25 μm or more, 1.5 μm or more, 1.75 μm or more, 2 μm or more, 2.25 μm or more, 2.5 μm or more, or 2.75 μm or more). In some examples, the collector layer 104 has an average thickness of 3 micrometers (microns, μm) or less (e.g., 2.75 μm or less, 2.5 μm or less, 2.25 μm or less, 2 μm or less, 1.75 μm or less, 1.5 μm or less, 1.25 μm or less, 1 μm or less, 950 nm or less, 900 nm or less, 850 nm or less, 800 nm or less, 750 nm or less, 700 nm or less, 650 nm or less, 600 nm or less, 550 nm or less, 500 nm or less, 450 nm or less, 400 nm or less, 350 nm or less, 300 nm or less, 275 nm or less, 250 nm or less, 225 nm or less, 200 nm or less, 175 nm or less, 150 nm or less, 140 nm or less, 130 nm or less, 120 nm or less, or 110 nm or less). The average thickness of the collector layer 140 can range from any of the minimum values described above to any of the maximum values described above. For example, the collector layer 140 can have an average thickness of from 100 nanometers (nm) to 3 micrometers (microns, μm) (e.g., from 100 nm to 1 μm, from 1 μm to 3 μm, from 100 nm to 400 nm, from 400 nm to 700 nm, from 700 nm to 1000 nm, from 1 μm to 1.5 μm, from 1.5 μm to 2 μm, from 2 μm to 2.5 μm, from 2.5 μm to 3 μm, from 100 nm to 2 μm, from 100 nm to 1.5 μm, from 100 nm to 900 nm, from 100 nm to 800 nm, from 100 nm to 700 nm, from 100 nm to 600 nm, from 100 nm to 500 nm, from 100 nm to 300 nm, from 100 nm to 200 nm, from 125 nm to 1000 nm, from 150 nm to 1000 nm, from 200 nm to 3 μm, from 300 nm to 3 μm, from 400 nm to 3 μm, from 500 nm to 3 μm, from 600 nm to 3 μm, from 800 nm to 3 μm, from 900 nm to 3 μm, from 150 nm to 2.5 μm, from 200 nm to 2 μm, or from 300 nm to 1 μm). The average thickness can be measured using methods known in the art, such as, for example, atomic force microscopy or electron microscopy.

In some examples, the collector layer 104 can have a composition that varies, such that the collector layer 104 has a compositional gradient, such as across the thickness. The compositional gradient can, for example, be a linear gradient, a stepped gradient, an exponential gradient, a logarithmic gradient, etc., or a combination thereof. The compositional gradient can, for example, be achieved by varying the composition during crystal growth.

In some examples, the collector layer 104 has a large critical electric field (e.g., 3 MV/cm or more).

In some examples, buffer layers can be utilized between the first substrate 102 and the collector layer 104, for example to improve device quality. In some examples, a contact layer can be present adjacent to the collector layer 104 (towards the first substrate 102), for example to improve the ability to make low-resistance contacts to the collector.

The base layer 106 can comprise any suitable material.

In an NPN HBT transistor structure, for example, the base layer 106 can comprise any suitable material that can be engineered to have a high hole mobility, a high hole velocity, a high hole concentration, or a combination thereof to reduce base contact and base layer resistances, such as a GaAs-based material. In some examples, the p-type base has a hole concentration greater than 1E19 cm⁻³, preferably greater than 5E19 cm⁻³. In some examples, the base's sheet resistance is less than 1000 ohm/sq, preferably less than 750 ohm/sq. In some examples, the contact resistance to the base layer is less than 1E-5 Ω-cm², preferably less than 1E-6 Ω-cm² and most preferably less than 1E-7 Ω-cm².

In PNP HBT configurations, the base layer 106 should be n-type and therefore engineered to have a high electron mobility, a high electron velocity, a high electron concentration, or a combination thereof. In some examples, the n-type base has an electron concentration greater than 1E19 cm⁻³, preferably greater than 5E19 cm⁻³. In some examples, the base's sheet resistance is less than 1000 ohm/sq, preferably less than 750 ohm/sq. In some examples, the contact resistance to the base layer is less than 1E-5 Ω-cm², preferably less than 1E-6 Ω-cm² and most preferably less than 1E-7 Ω-cm².

In some examples, the base layer 106 can comprise a GaAs-based material (e.g. a material comprising GaAs).

In some examples, the base layer 106 comprises In_{y}Ga_{1-y}As, wherein y is from 0 to 1. For example, y can be 0 or more (e.g., 0.1 or more, 0.2 or more, 0.3 or more, 0.4 or more, 0.5 or more, 0.6 or more, 0.7 or more, 0.8 or more, or 0.9 or more). In some examples, y can be 1 or less (e.g., 0.9 or less, 0.8 or less, 0.7 or less, 0.6 or less, 0.5 or less, 0.4 or less, 0.3 or less, 0.2 or less, or 0.1 or less). The value of y can range from any of the minimum values described above to any of the maximum values described above. For example, y can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.5, from 0 to 0.4, from 0 to 0.3, from 0 to 0.2, from 0 to 0.1, from 0.1 to 1, from 0.2 to 1, from 0.3 to 1, from 0.4 to 1, from 0.5 to 1, from 0.6 to 1, from 0.7 to 1, from 0.8 to 1, from 0.9 to 10, from 0.1 to 0.9, from 0.2 to 0.8, or from 0.3 to 0.7).

In some examples, the base layer 106 comprises GaAsₐSb₁₋ₐ, wherein a is from 0 to 1. For example, a can be 0 or more (e.g., 0.1 or more, 0.2 or more, 0.3 or more, 0.4 or more, 0.5 or more, 0.6 or more, 0.7 or more, 0.8 or more, or 0.9 or more). In some examples, a can be 1 or less (e.g., 0.9 or less, 0.8 or less, 0.7 or less, 0.6 or less, 0.5 or less, 0.4 or less, 0.3 or less, 0.2 or less, or 0.1 or less). The value of a can range from any of the minimum values described above to any of the maximum values described above. For example, a can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.5, from 0 to 0.4, from 0 to 0.3, from 0 to 0.2, from 0 to 0.1, from 0.1 to 1, from 0.2 to 1, from 0.3 to 1, from 0.4 to 1, from 0.5 to 1, from 0.6 to 1, from 0.7 to 1, from 0.8 to 1, from 0.9 to 10, from 0.1 to 0.9, from 0.2 to 0.8, or from 0.3 to 0.7).

In some examples, the base layer 106 is lattice-matched or pseudomorphically strained to an InP lattice constant. In some examples, the base layer 106 can comprise In, Al, Ga, As, Sb, or a combination thereof (e.g., InAlGaAsSb).

In some examples, the base layer 106 comprises In_{0.53}Ga_{0.47}As, GaAs, InAlGaAs, InGaAsP, or a combination thereof. In some examples, the base layer 106 comprises In_{y}Ga_{1-y}As and the collector layer 104 comprises AlₓGa₁₋ₓN. In some examples, the base layer 106 comprises In_{0.53}Ga_{0.47}As and the collector layer 104 comprises GaN. In some examples, the base layer 106 comprises In_{0.53}Ga_{0.47}As and the collector layer 104 comprises Al_{0.7}Ga_{0.3}N.

The base layer 106 can, for example, have an average thickness of 20 nm or more (e.g., 25 nm or more, 30 nm or more, 35 nm or more, 40 nm or more, 45 nm or more, 50 nm or more, 60 nm or more, 70 nm or more, 80 nm or more, 90 nm or more, 100 nm or more, 125 nm or more, 150 nm or more, 175 nm or more, 200 nm or more, 225 nm or more, 250 nm or more, 275 nm or more, 300 nm or more, 325 nm or more, 350 nm or more, 375 nm or more, 400 nm or more, 425 nm or more, 450 nm or more, or 475 nm or more). In some examples, the base layer 106 can have an average thickness of 500 nm or less (e.g., 475 nm or less, 450 nm or less, 425 nm or less, 400 nm or less, 375 nm or less, 350 nm or less, 325 nm or less, 300 nm or less, 275 nm or less, 250 nm or less, 225 nm or less, 200 nm or less, 175 nm or less, 150 nm or less, 125 nm or less, 100 nm or less, 90 nm or less, 80 nm or less, 70 nm or less, 60 nm or less, 50 nm or less, 45 nm or less, 40 nm or less, 35 nm or less, 30 nm or less, or 25 nm or less). The average thickness of the base layer 106 can range from any of the minimum values described above to any of the maximum values described above. For example, the base layer 106 can have an average thickness of from 20 nm to 500 nm (e.g., from 20 nm to 250 nm, from 250 nm to 500 nm, from 20 nm to 100 nm, from 200 nm to 300 nm, from 300 nm to 400 nm, from 400 nm to 500 nm, from 20 nm to 400 nm, from 20 nm to 300 nm, from 20 nm to 200 nm, from 20 nm to 50 nm, from 50 nm to 500 nm, from 100 nm to 500 nm, from 200 nm to 500 nm, from 300 nm to 500 nm, from 25 nm to 475 nm, from 50 nm to 450 nm, or from 100 nm to 400 nm). The average thickness can be measured using methods known in the art, such as, for example, atomic force microscopy or electron microscopy.

In some examples, the base layer 106 can have a composition that varies, such that the base layer 106 has a compositional gradient, such as across the thickness. The compositional gradient can, for example, be a linear gradient, a stepped gradient, an exponential gradient, a logarithmic gradient, etc., or a combination thereof.

The emitter layer 108 can comprise any suitable material. For example, the emitter layer 108 can comprise any suitable material whose bandgap is larger than the bandgap of the base layer 106. In some examples, the emitter layer 108 can comprise InP, InAlGaAs, InAlAs, InGaAsP, or a combination thereof. In some examples, the emitter layer 108 comprises an InP-based material (e.g., a material comprising InP). In some examples, the base layer can comprise GaAs or InGaAs, and the emitter layer 108 can comprise InP, InAlGaAs, InAlAs, InGaAsP, or a combination thereof.

The emitter layer 108 can, for example, have an average thickness of 20 nm or more (e.g., 25 nm or more, 30 nm or more, 35 nm or more, 40 nm or more, 45 nm or more, 50 nm or more, 60 nm or more, 70 nm or more, 80 nm or more, 90 nm or more, 100 nm or more, 125 nm or more, 150 nm or more, 175 nm or more, 200 nm or more, 225 nm or more, 250 nm or more, 275 nm or more). In some examples, the emitter layer 108 can have an average thickness of 300 nm or less (e.g., 275 nm or less, 250 nm or less, 225 nm or less, 200 nm or less, 175 nm or less, 150 nm or less, 125 nm or less, 100 nm or less, 90 nm or less, 80 nm or less, 70 nm or less, 60 nm or less, 50 nm or less, 45 nm or less, 40 nm or less, 35 nm or less, 30 nm or less, or 25 nm or less). The average thickness of the emitter layer 108 can range from any of the minimum values described above to any of the maximum values described above. For example, the emitter layer 108 can have an average thickness of from 20 nm to 300 nm (e.g., from 20 nm to 150 nm, from 150 nm to 300 nm, from 20 nm to 100 nm, from 100 nm to 200 nm, from 200 nm to 300 nm, from 20 nm to 250 nm, from 20 nm to 200 nm, from 20 nm to 50 nm, from 50 nm to 300 nm, from 100 nm to 300 nm, from 250 nm to 300 nm, from 25 nm to 275 nm, from 50 nm to 250 nm, or from 75 nm to 225 nm). The average thickness can be measured using methods known in the art, such as, for example, atomic force microscopy or electron microscopy.

In some examples, the emitter layer 108 can have a composition that varies, such that the emitter layer 108 has a compositional gradient, such as across the thickness. The compositional gradient can, for example, be a linear gradient, a stepped gradient, an exponential gradient, a logarithmic gradient, etc., or a combination thereof.

In some examples, the collector layer 104, the base layer 106, and the emitter layer 108 each independently further comprise a dopant. The identity of each dopant and/or the concentration of each dopant can be selected in view of a variety of factors. In some examples, the concentration of the dopant in each layer can vary, such that each layer has a dopant gradient, such as across the thickness. The dopant gradient can, for example, be a linear gradient, a stepped gradient, an exponential gradient, a logarithmic gradient, etc., or a combination thereof.

In some examples, the collector layer 104 comprises an n-type material, the base layer 106 comprises a p-type material, and the emitter layer 108 comprises an n-type material, such that the heterogeneous heterojunction bipolar transistor (HBT) device 100 has an NPN structure. In some examples, the collector layer 104 includes an n-type dopant, the base layer 106 includes a p-type dopant, and the emitter layer 108 includes an n-type dopant. In some examples, the collector layer 104 comprises an n-type group III-nitride. In some examples, the base layer 106 comprises a p-type GaAs-based material (e.g., a p-type material comprising GaAs or InₓGa₁₋ₓAs where x is from 0 to 1).

In some examples, the collector layer 104 comprises a p-type material, the base layer 106 comprises an n-type material, and the emitter layer 108 comprises a p-type material, such that the heterogenous heterojunction bipolar transistor (HBT) device 100 has a PNP structure. In some examples, the collector layer 104 includes a p-type dopant, the base layer 106 includes an n-type dopant, and the emitter layer 108 includes a p-type dopant.

The second substrate 120 can comprise any suitable material. For example, the second substrate can comprise any suitable material to realize low defect density crystal growth (e.g., preferably 1E4 cm⁻², alternatively <1E5 cm⁻², or at least <5E6 cm⁻²). In some examples, the second substrate 120 comprises an InP-based material (e.g., a material comprising InP). In some examples, the second substrate 120 comprises InP.

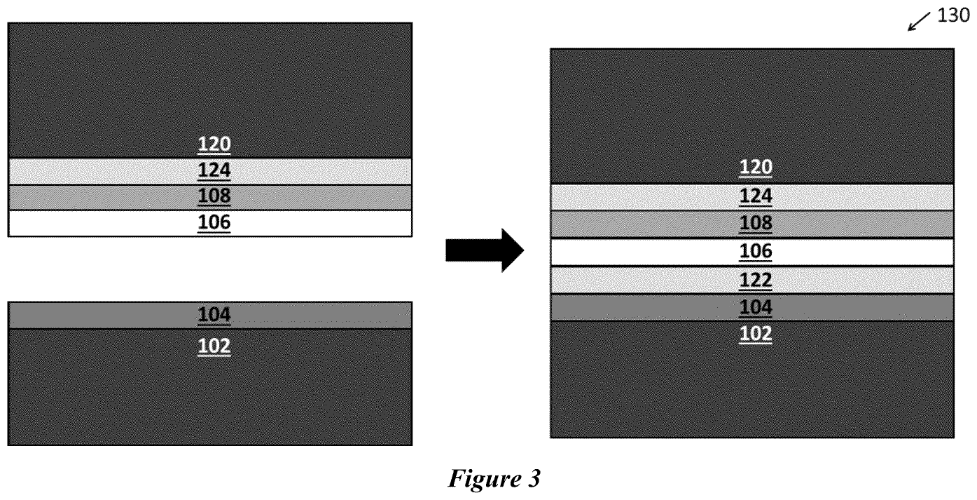

Referring now to FIG. 3, in some examples, the methods further comprise depositing a release layer 124 on the second substrate 120, subsequently depositing the emitter layer 108 on the release layer 124, and subsequently depositing the base layer 106 on the emitter layer 108. For example, such that the precursor device 130 further comprises the release layer 124 wherein the release layer 124 disposed on top of an in physical contact with the emitter layer 108, such that the emitter layer 108 is disposed between and in physical contact with the base layer 106 and the release layer 124, and the second substrate 120 is disposed on top of an in physical contact with the release layer 124, such that the release layer 124 is disposed between and in physical contact with the emitter layer 108 and the second substrate 120. Etching the precursor device 130 can, for example, comprise etching the release layer 124 to thereby remove the release layer 124 and the second substrate 120 to form the heterogeneous heterojunction bipolar transistor (HBT) device 100.

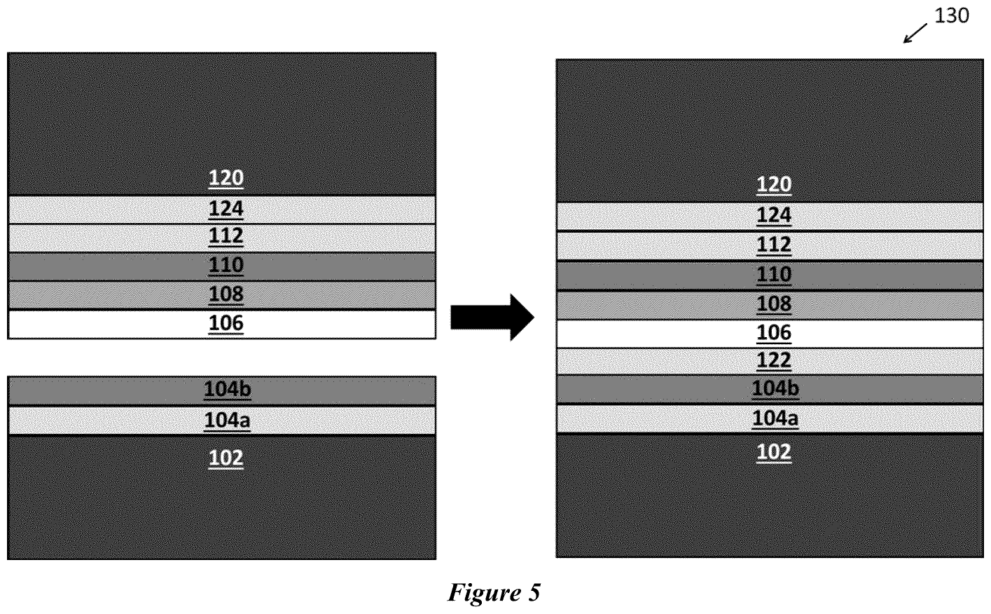

Referring now to FIG. 5 and FIG. 7, in some examples, the collector layer 104 comprises a first collector layer 104a (e.g., a subcollector layer 104a) and a second collector layer 104b, and the method comprises depositing the first collector layer 104a on the first substrate 102 and subsequently depositing the second collector layer 104b on the first collector layer 104a, such that in the precursor device 130 the first collector layer 104a is disposed on and in physical contact with the first substrate 102, and the second collector layer 104b is disposed on and in physical contact with the first collector layer 104a, such that the first collector layer 104a is disposed between and in physical contact with the first substrate 102 and the second collector layer 104b.

The first collector layer 104a can, for example, be referred to as a subcollector layer. For high-frequency applications of HBT's, it is preferred that the first substrate 102 be an insulating or semi-insulating substrate. In some examples, a semi-insulating first substrate 102 has a resistivity greater than 1E6 Ω·cm, preferably greater than 1E9 Ω·cm. The subcollector layer 104a is thus designed to permit low resistance contacts to the collector layer. In some examples, the carrier concentration (electron or hole) is greater than 1E19 cm⁻³, preferably greater than 5E19 cm⁻³. In some examples, the subcollector layer's sheet resistance is less than 1000 ohm/sq, preferably less than 750 ohm/sq. In some examples, the contact resistance to the subcollector layer is less than 1E-5 Ω-cm², preferably less than 1E-6 Ω-cm² and most preferably less than 1E-7 Ω-cm².

For example, the methods and or device can comprise one or more collector layers 104 (e.g., 104a, 104b). In some examples, the one or more collector layers 104 can be included to provide transition layers for the base-collector junction, to provide a highly doped sub-collector layer, or a combination thereof.

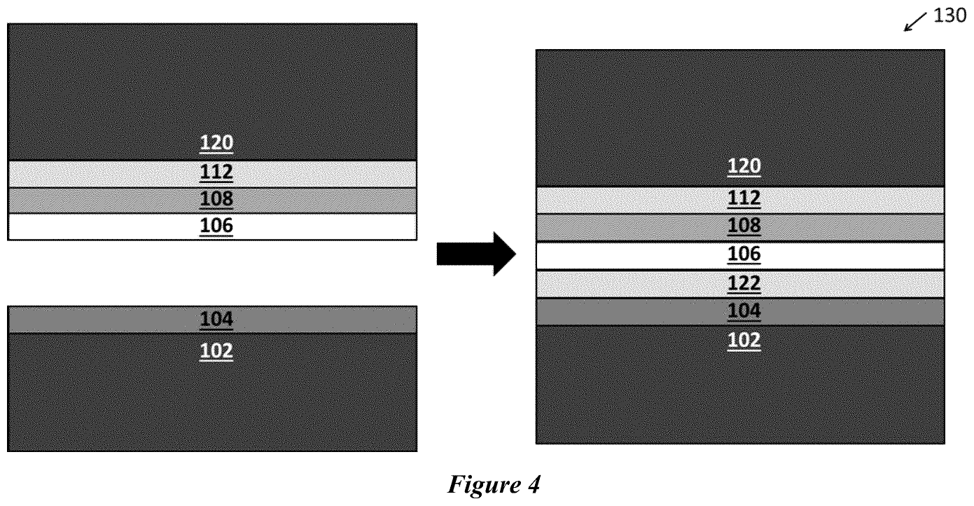

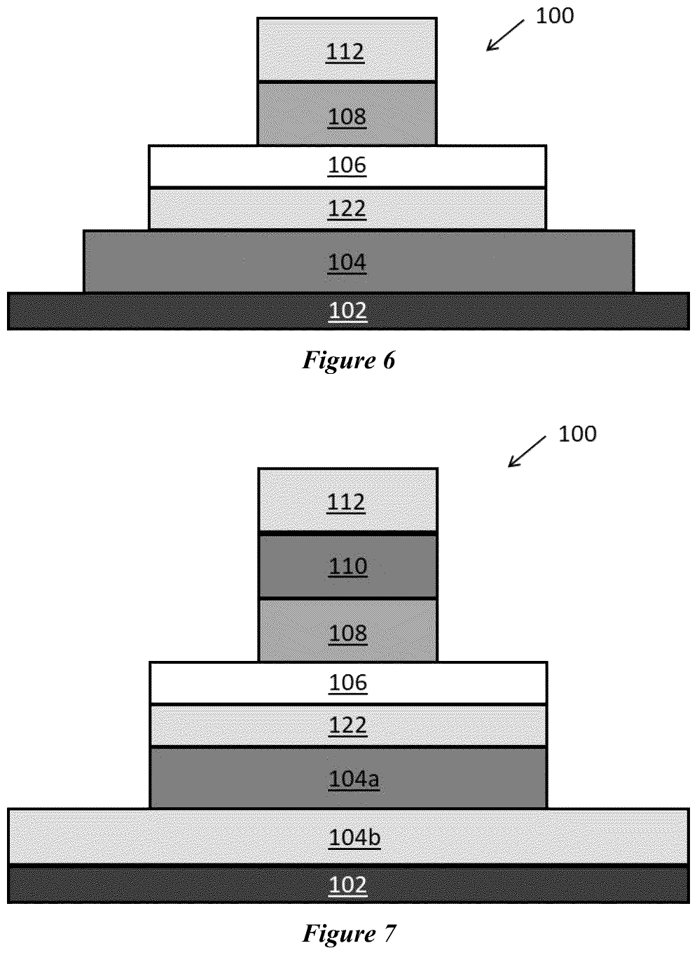

In some examples, the methods further comprise depositing one or more additional layers 110, 112 on the second substrate 120 before depositing the emitter layer 108, such that the precursor device 130 further comprises the one or more additional layers, e.g. layers 110, 112, which are disposed between and in physical contact with the emitter layer 108 and the release layer 124 (when present) or the second substrate 120 (when the release layer 124 is absent), as shown in FIG. 4-FIG. 5 and the corresponding HBT devices 100 shown in FIG. 6-FIG. 7. The one or more additional layers can each independently comprise any suitable material.

For example, layer 110 can comprise a graded layer to connect the contact and emitter layer 108.

For example, layer 112 can comprise a contact layer.

The one or more additional layers can, for example, be included to engineer the base-collector junction, to enhance carrier transport across the base layer, to adjust the interaction with the contacts, or a combination thereof.

In some examples, buffer layers can also be utilized between the substrate and release layer 124 to improve device quality. In some examples, a contact layer can be present adjacent to the emitter layer (towards the 120 substrate side) to improve the ability to make low-resistance contacts to the emitter layer.

In some examples, the methods further comprise depositing one or more contacts on the device. Each of the one or more contacts can, for example, independently comprise a metal, such as any suitable metal. In some examples, each of the one or more contacts can independently comprise a metal selected from the group consisting of V, Cr, Ti, Al, Ni, Au, Pt, Ge, Ni, W, Pd, or a combination thereof. In some examples, each of the one or more contacts can, for example, comprise one or more layers, each layer independently comprising one or more metals, for example selected from the group consisting of V, Cr, Ti, Al, Ni, Au, Pt, Ge, Ni, W, Pd, or a combination thereof.

In some examples, additional metallization and barrier layers can be utilized to interconnect the contacts to the package (e.g., wire bonding, bumping, or other means known in the art). Such interconnect metallizations can comprise any suitable metal. For example, the interconnect metallizations can comprise Al, Au, Cu, or a combination thereof.

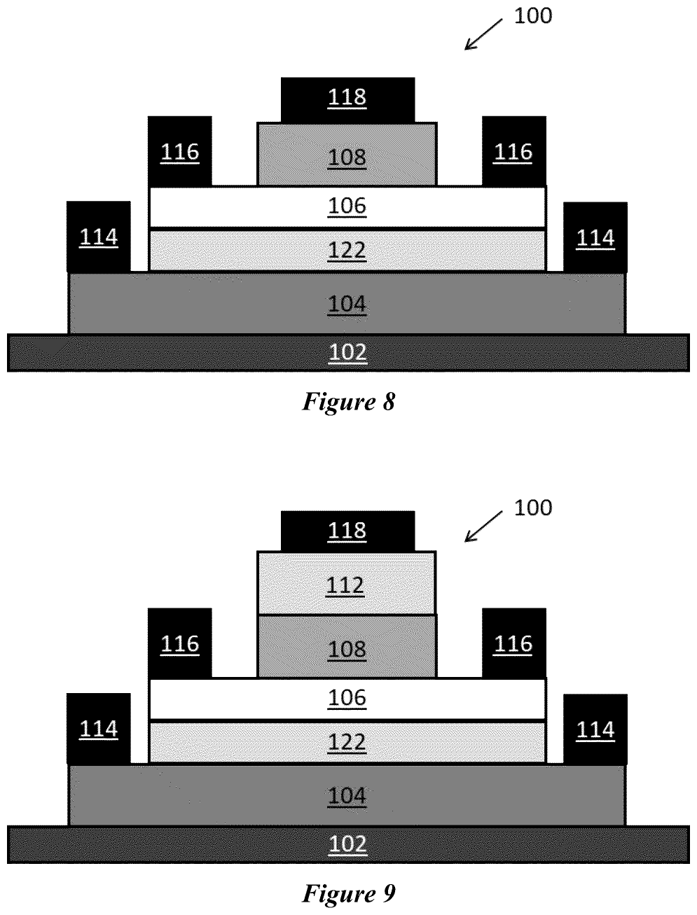

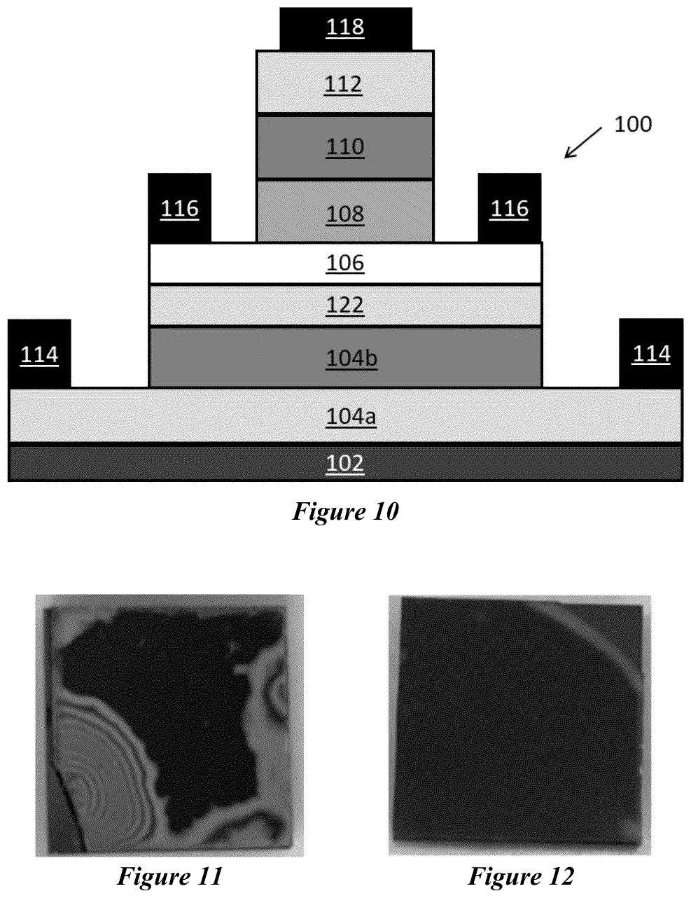

In some examples, the method comprises depositing a first contact 114 comprising a first metal on at least a portion of the collector layer 104, depositing a second contact 116 comprising a second metal on at least a portion of the base layer 106, depositing a third contact 118 comprising a third metal on at least a portion of the emitter layer 108 and/or at least a portion of one of the one or more additional layers 110, 112 (when present), or a combination thereof, for example as shown in FIG. 8-FIG. 10. In some examples, the first metal, the second metal, and the third metal (when present) are each independently selected from the group consisting of V, Cr, Ti, Al, Ni, Au, Pt, Ge, Ni, W, Pd, or a combination thereof.

The order of the metallization can be changed based on the best way to realize the device. Furthermore, additional processing (e.g., to realize access to each of the emitter, base, and collector and/or define the appropriate geometries) can also be performed.

In some examples, any of the layers (e.g., 102, 104, 106, 108, 110, 112, 120, 122, and/or 124) can optionally be patterned, for example to control and/or adjust the stress and/or strain. For example, the methods can further comprise patterning any of the layers (e.g., 102, 104, 106, 108, 110, 112, 120, 122, and/or 124).

Also disclosed herein are heterogeneous heterojunction bipolar transistor (HBT) devices 100 made by any of the methods disclosed herein.

Also disclosed herein are heterogeneous heterojunction bipolar transistor (HBT) devices 100 comprising a first substrate 102, a collector layer 104, an interface 122, a base layer 106, and an emitter layer 108, wherein: the collector layer 104 is disposed on top of and in physical contact with the first substrate 102; the interface 122 is disposed on top of and in physical contact with the collector layer 104, such that the collector layer 104 is disposed between and in physical contact with the first substrate 102 and the interface 122; the base layer 106 is disposed on top of and in physical contact with the interface 122, such that the interface 122 is disposed between and in physical contact with the collector layer 104 and the base layer 106; and the emitter layer 108 is disposed on top of and in physical contact with the base layer 106, such that the base layer 106 is disposed between and in physical contact with the interface 122 and the emitter layer 108. In some examples, the first substrate 102 comprises Al_{w}Ga_{1-w}N where w is from 0 to 1 (e.g., GaN. AlN). In some examples, the collector layer 104 is epitaxially grown on the first substrate 102. In some examples, the collector layer 104 comprises a group III-nitride based material. In some examples, the emitter layer 108 has a lattice-constant and/or a crystal structure that is different than that of the base layer 106 and/or the collector layer 104. In some examples, the emitter layer 108 and the base layer 106 have a lattice constant that is lattice-matched to InP. In some examples, the collector layer 104 has a first band gap, the emitter layer 108 has a second bandgap, and the base layer 106 has a third bandgap; the first bandgap (e.g., the bandgap of the collector layer 104) is greater than the third bandgap (e.g., the bandgap of the base layer 106); and the second band gap (e.g., the bandgap of the emitter layer 108) is greater than the third bandgap (e.g., the bandgap of the base layer 106).

In some examples, the emitter layer has a hexagonal and/or zinc-blende crystal structure.

In some examples, the interface 122 is formed using wafer bonding (e.g., the interface 122 is a wafer-bonded interface). In some examples, the interface 122 is formed using crystal heterogeneous integration wafer bonding (e.g. the interface 122 is a CHI interface).

In some examples, the first substrate 102 and the collector layer 104 have a lattice mismatch of 30% or less.

In some examples, the first substrate 102 is a low-dislocation material and/or a material with a large thermal conductivity.

In some examples, the first substrate 102 comprises GaN and the collector layer 104 comprises AlₓGa₁₋ₓN, wherein x is from 0 to 0.5, from 0 to 0.3, or from 0 to 0.15. In some examples, the first substrate 102 comprises GaN and the collector layer 104 comprises GaN. In some examples, the first substrate 102 comprises AlN and the collector layer 104 comprises AlₓGa₁₋ₓN, wherein x is from 0.5 to 1, from 0.7 to 1, or from 0.85 to 1. In some examples, the collector layer 104 comprises GaN, AlₓGa₁₋ₓN wherein x is from 0 to 0.3 (e.g., Al_{0.7}Ga_{0.3}N), or a combination thereof.

In some examples, the collector layer 104 has an average thickness of from 100 nanometers (nm) to 3 micrometers (microns, μm).

In some examples, the collector layer 104 has a large critical electric field.

In some examples, the base layer 106 comprises a GaAs-based material (e.g., a material comprising GaAs). In some examples, the base layer 106 comprises In_{y}Ga_{1-y}As, wherein y is from 0 to 1. In some examples, the base layer 106 comprises In_{y}Ga_{1-y}As, wherein y is from 0.52 to 0.53. In some examples, the base layer 106 comprises GaAsₐSb₁₋ₐ, wherein a is from 0 to 1. In some examples, the base layer 106 comprises In_{0.53}Ga_{0.47}As, GaAs, InAlGaAs, InGaAsP, or a combination thereof.

In some examples, the base layer 106 has an average thickness of from 20 nm to 500 nm.

In some examples, the base layer 106 comprises In_{y}Ga_{1-y}As and the collector layer 104 comprises AlₓGa₁₋ₓN. In some examples, the base layer 106 comprises In_{0.53}Ga_{0.47}As and the collector layer 104 comprises GaN. In some examples, the base layer 106 comprises In_{0.53}Ga_{0.47}As and the collector layer 104 comprises Al_{0.7}Ga_{0.3}N.

In some examples, the emitter layer comprises InP, InAlGaAs, InAlAs, InGaAsP, or a combination thereof. In some examples, the emitter layer 108 comprises an InP-based material. In some examples, the emitter layer comprises InP.

In some examples, the emitter layer 108 has an average thickness of from 20 nm to 300 nm.

In some examples, the collector layer 104, the base layer 106, and the emitter layer 108 each independently further comprise a dopant.

In some examples, the collector layer 104 comprises an n-type material, the base layer 106 comprises a p-type material, and the emitter layer 108 comprises an n-type material, such that the heterogeneous heterojunction bipolar transistor (HBT) device 100 has an NPN structure.

In some examples, the collector layer 104 includes an n-type dopant, the base layer 106 includes a p-type dopant, and the emitter layer 108 includes an n-type dopant.

In some examples, the collector layer 104 comprises an n-type group III-nitride.

In some examples, the base layer 106 comprises a p-type GaAs-based material.

In some examples, the collector layer 104 comprises a p-type material, the base layer 106 comprises an n-type material, and the emitter layer 108 comprises a p-type material, such that the heterogeneous heterojunction bipolar transistor (HBT) device 100 has a PNP structure.

In some examples, the collector layer 104 includes a p-type dopant, the base layer 106 includes an n-type dopant, and the emitter layer 108 includes a p-type dopant.

In some examples, the collector layer 104 comprises a first collector layer 104a and a second collector layer 104b, and the first collector layer 104a is disposed on and in physical contact with the first substrate 102, and the second collector layer 104b is disposed on and in physical contact with the first collector layer 104a, such that the first collector layer 104a is disposed between and in physical contact with the first substrate 102 and the second collector layer 104b.

In some examples, the device further comprises one or more additional layers 110 and/or 112, which are disposed on and in physical contact with the emitter layer 108.

In some examples, the device further comprises one or more BEG layers at one or both sides of the interface layer. In some examples, each of the one or more BEG layers independently comprises InGaAs, InAlGaAs, GaAsSb, AlGaAsSb, or a combination thereof.

In some examples, the device further comprises one or more contacts on the device. Each of the one or more contacts can, for example, independently comprise a metal, such as a metal selected from the group consisting of V, Cr, Ti, Al, Ni, Au, Pt, Ge, Ni, W, Pd, or a combination thereof. In some examples, the device further comprises a first contact 114 comprising a first metal deposited on at least a portion of the collector layer 104, a second contact 116 comprising a second metal deposited on at least a portion of the base layer 106, depositing a third contact 118 comprising a third metal deposited on at least a portion of the emitter layer 108 and/or at least a portion of one of the one or more additional layers 110, 112 (when present), or a combination thereof. In some examples, the first metal, the second metal, and the third metal (when present) are each independently selected from the group consisting of V, Cr, Ti, Al, Ni, Au, Pt, Ge, Ni, W, Pd, or a combination thereof.

In some examples, the device is made by any of the methods disclosed herein.

Example heterogeneous heterojunction bipolar transistor (HBT) devices 100 are shown in FIG. 2 and FIG. 6-FIG. 10.

Also disclosed herein are methods of use of any of the devices disclosed herein.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the devices and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, and temperature is in° C. or is at ambient temperature. There are numerous variations and combinations of measurement conditions, e.g., component concentrations, temperatures, pressures and other measurement ranges and conditions that can be used to optimize the described process.

These examples describe the heterogeneous integration of III-V and III-N materials that cannot be integrated via direct epitaxy due to the large lattice mismatch, and thus necessitate the use of CHI for the formation of HBTs.

### Example 1

Previous work seeking to integrate III-V layers with III-N layers to form the base-collector (B-C) junction of HBTs has focused on bonding p-type GaAs to n-type GaN. This is because direct heteroepitaxy of III-V on III-N's (and vice versa) does not yield high quality layers due to the large lattice mismatch, and dissimilar crystal structure (i.e., cubic vs. hexagonal) [1]. Traditional approaches to bonding were limited to (1) high interface defect densities due to defective GaN films obtained from heteroepitaxy on sapphire, (2) low temperature bonding to lower the risk of III-V decomposition and manage large CTE mismatches between substrates, (3) no or dielectric-based interface layers that increase the risk of a large band discontinuity, (4) low thermal conductivity substrates and large TBR's that limit high power performance, and (5) suboptimal breakdown performance due to the large dislocation density in heteroepitaxially grown GaN. The methods and devices described herein address these limitations, for example, by (1) using homoepitaxially grown GaN-on-GaN films or low-dislocation density AlGaN-on-GaN or AlGaN-on-AlN films, (2) unlocking higher temperature bonding by choosing substrates with low CTE mismatch and adopting CHI, a wafer bonding process that permits the use of Column V bonding atmospheres that prevent surface decomposition, (3) the use of semiconductor-based interface layers that can tune the band offset at the interface and promote carrier transport, (4) the use of high thermal conductivity GaN and AlN substrates and, in the case of homoepitaxy, low thermal boundary resistance (TBR) between the collector and the substrate for efficient thermal dissipation, and/or (5) potential to achieve near-ideal breakdown fields in the collector due to the use of GaN and AlN substrates for low dislocation density collector growth. Example differences between the methods and devices disclosed herein relative to previous work is provided in the table below. Note that for purposes of this description, AlGaN refers to AlₓGa₁₋ₓN. For AlGaN-on-GaN, x is between 0 and 0.3, or preferably 0 and 0.15 for low-defect density. For AlGaN-on-AlN, x is between 0.7 and 1.0, or preferably 0.85 and 1.0 for low-defect density.

| Device | | | |
|---|---|---|---|
| Attribute | Parameter | Previous Work | Difference |
| B-C interface | III-Nitride | Heteroepitaxy on | Homoepitaxy (GaN-on-GaN, |
| trap density | Epitaxy | high-dislocation | AlGaN-on-GaN, AlN-on-AlN) |
| | | substrate (e.g., GaN- | or Heteroepitaxy on low- |
| | | on-sapphire) [2]-[4] | dislocation substrate (AlGaN- |
| | | | on-AlN) |
| | Substrate CTE | GaAs to Sapphire | InP to GaN (2%) or InP to AlN |
| | Mismatch | (7%) or InP to | (−2%) |
| | | Sapphire (57%) | |
| | Bonding | N₂ [2], [3] | N₂, Ar, H₂ + Column V |
| | atmosphere | | Precursors (e.g., TBAs, TBP, |
| | | | NH₄) + Dopants (e.g., Si, Mg) |
| B-C band | Interfacial Layers | Direct bonding (no | Band-Engineering and Glue |
| offset | | interfacial layers) [2]- | (BEG) Layers composed on |
| | | [4], or dielectric- | semiconductor materials (III- |
| | | based glue layer [5], | V, III-N) meant to bend the |
| | | [6] | bands, as well as improve |
| | | | bond strength |
| Wafer bond | Bonding | 400-550° C. [2]-[4] | 500-700° C. |
| strength | temperature | | |
| | Interfacial Layers | Direct bonding (no | Band-Engineering and Glue |
| | | interfacial layers) [2]- | (BEG) Layers composed on |
| | | [4], or dielectric- | semiconductor materials (III- |
| | | based glue layer [5], | V, III-N) meant to bend the |
| | | [6] | bands, as well as improve |
| | | | bond strength |
| Collector | Low dislocation | Heteroepitaxy on | Homoepitaxy (GaN-on-GaN, |
| Breakdown | density in | high-dislocation | AlN-on-AlN) or Heteroepitaxy |
| Field | Collector | substrate (e.g., GaN- | on low-dislocation substrate |
| | Material | on-sapphire) [2]-[4] | (AlGaN-on-AlN) [7], [8] |
| Thermal | III-Nitride | Sapphire | GaN, AlN [9], [10] |
| | Substrate | | |
| Conductivity | Thermal | GaN-to-buffer-to- | GaN-on-GaN, AlN-on-AlN [9] |
| | Boundary | nucleation layers-to | |
| | Resistance | substrate [11] | |
| | between | | |
| | Collector and | | |
| | Substrate | | |

### REFERENCES

[1] J. Wu, H. Yaguchi, K. Onabe, Y. Shiraki, and R. Ito, “Metalorganic Vapor Phase Epitaxy Growth of High Quality Cubic GaN on GaAs (100) Substrates,” Jpn. J. Appl. Phys., vol. 37, no. 3S, p. 1440 Mar. 1998, doi: 10.1143/JJAP.37.1440.
[2] C. Lian, H. G. Xing, Y.-C. Chang, and N. Fichtenbaum, “Electrical transport properties of wafer-fused p-GaAs/n-GaN heterojunctions,” Appl. Phys. Lett., vol. 93, no. 11, p. 112103, September 2008, doi: 10.1063/1.2983648.
[3] J. Kim, N. G. Toledo, S. Lal, J. Lu, T. E. Buehl, and U. K. Mishra, “Wafer-Bonded p-n Heterojunction of GaAs and Chemomechanically Polished N-Polar GaN,” IEEE Electron Device Lett., vol. 34, no. 1, pp. 42-44, January 2013, doi: 10.1109/LED.2012.2225137.
[4] S. Lal, E. Snow, J. Lu, B. Swenson, S. Keller, S. P. Denbaars, and U. K. Mishra, “InGaAs-InGaN Wafer-Bonded Current Aperture Vertical Electron Transistors (BAVETs),” J. Electron. Mater., vol. 41, no. 5, pp. 857-864, May 2012, doi: 10.1007/s11664-012-1977-x.
[5] S. J. Cho, D. Liu, A. Hardy, J. Kim, J. Gong, C. J. Herrera-Rodriguez, E. Swinnich, X. Konstantinou, G.-Y. Oh, D. G. Kim, J. C. Shin, J. Papapolymerou, M. Becker, J.-H. Seo, J. D. Albrecht, T. A. Grotjohn, and Z. Ma, “Fabrication of AlGaAs/GaAs/diamond heterojunctions for diamond-collector HBTs,” AIP Adv., vol. 10, no. 12, p. 125226, December 2020, doi: 10.1063/5.0027864.
[6] D. Liu, S. J. Cho, J.-H. Sco, K. Kim, M. Kim, J. Shi, X. Yin, W. Choi, C. Zhang, J. Kim, M. A. Baboli, J. Park, J. Bong, I.-K. Lec, J. Gong, S. Mikael, J. H. Ryu, P. K. Mohseni, X. Li, S. Gong, X. Wang, and Z. Ma, “Lattice-mismatched semiconductor heterostructures,” ArXiv181210225 Phys., December 2018, Accessed: May 3, 2021. [Online]. Available: http://arxiv.org/abs/1812.10225.
[7] L. Cao, Z. Zhu, G. Harden, H. Ye, J. Wang, A. Hoffman, and P. J. Fay, “Temperature Dependence of Electron and Hole Impact Ionization Coefficients in GaN,” IEEE Trans. Electron Devices, vol. 68, no. 3, pp. 1228-1234 Mar. 2021, doi: 10.1109/TED.2021.3054355.
[8] D. Khachariya, S. Mita, P. Reddy, S. Dangi, J. H. Dycus, P. Bagheri, M. H. Breckenridge, R. Sengupta, S. Rathkanthiwar, R. Kirste, E. Kohn, Z. Sitar, R. Collazo, and S. Pavlidis, “Record >10 MV/cm mesa breakdown fields in A10.85Ga0.15N/A10.6Ga0.4N high electron mobility transistors on native AlN substrates,” Appl. Phys. Lett., vol. 120, no. 17, p. 172106, April 2022, doi: 10.1063/5.0083966.
[9] G. Alvarez-Escalante, R. Page, R. Hu, H. G. Xing, D. Jena, and Z. Tian, “High thermal conductivity and ultrahigh thermal boundary conductance of homoepitaxial AlN thin films,” APL Mater., vol. 10, no. 1, p. 011115, January 2022, doi: 10.1063/5.0078155.
[10] R. Rounds, B. Sarkar, D. Alden, Q. Guo, A. Klump, C. Hartmann, T. Nagashima, R. Kirste, A. Franke, M. Bickermann, Y. Kumagai, Z. Sitar, and R. Collazo, “The influence of point defects on the thermal conductivity of AlN crystals,” J. Appl. Phys., vol. 123, no. 18, p. 185107, May 2018, doi: 10.1063/1.5028141.
[11] A. Manoi, J. W. Pomeroy, N. Killat, and M. Kuball, “Benchmarking of Thermal Boundary Resistance in AlGaN/GaN HEMTs on SiC Substrates: Implications of the Nucleation Layer Microstructure,” IEEE Electron Device Lett., vol. 31, no. 12, pp. 1395-1397 Dec. 2010, doi: 10.1109/LED.2010.2077730.

### Example 2

Described herein are heterogeneously integrated ultra-wide band gap (UWBG) and wide band gap (WBG) heterojunction bipolar transistors (HBTs). High-power, high-speed transistor structures are disclosed with a figure of merit 15-35× that of conventional devices using new heterogeneously integrated device structures and processes. The devices described herein can be used as high-power, high speed transistors for wireless applications, radar, instruments, etc. The devices described herein have >10× better speed and power than other existing devices.

There are a number of new ideas for heterogeneously integrated InP-based (emitter-base) to AlGaN-based (collector) HBTs, such as:
HBT using AlₓGa₁₋ₓN/AlN epitaxially deposited on bulk GaN or bulk AlN substrates as collector
InP-(In)GaAs-AlGaN HBT
Use of bulk GaN or AlN substrates for low-defect density and high thermal conductivity
Use of Band-Engineering and Glue Semiconductor (BEG) Layers at III-N or III-As/P Interface at base-collector
Use of Crystal Heterogeneous Integration (CHI) for Wafer Fusion process, such as:
   Column V overpressure (e.g., using gases comprising As, P, and/or N)
   Addition of dopants (n or p type) at fused interface (e.g., using gases with n-type or p-type dopants)

As used herein, Crystal Heterogeneous Integration (CHI) is a method of fusing two semiconductor layers together by the steps of: (i) separating the wafers, (ii) heating them in an environment that contains at least one gas that serves as a dopant, etching, or source of column V overpressure, (iii) applying force (e.g., 1-100 MPa) at an elevated temperature (e.g., 400° C.-1000° C., preferably 500° C.-1000° C., and most preferably from greater than 600° C. to 1000° C.). A CHI interface is one that is said to have the characteristics of a wafer bonded interface. It is believed that one such characteristic is a different nature of misfit dislocations formed at the wafer bonded interface, compared to an epitaxially grown mismatched heterointerface. An interface that has undergone wafer bonding has been observed to exhibit misfit dislocations which primarily consist of “edge dislocations,” i.e. dislocations whose Burgers vector lies in the plane of the wafer bonded interface. These properties are in contrast to an epitaxially grown mismatched interface, which typically exhibits a much higher density of “threading dislocations,” i.e. dislocations which are not confined to the plane of the mismatched interface and tend to propagate perpendicular to the interface. Furthermore, the CHI interface can further have the characteristics that include at least one of (i) reduced or absent areas of column V decomposition of the wafer surface, (ii) absence of oxides at the interface, (iii) increased doping at the interface. In the case of (i), the areas of decomposition can be absent or can comprise <20% of the defected areas. In the case of absence of oxides, oxygen concentration <1E16 cm⁻², preferably <1E15 cm⁻² is present at the interface, in the case of dopants, an increased electron or hole concentration >2× that of the concentration adjacent to the interface. Another characteristic of the of a CHI interface is increased bond strength at the interface. Specifically, the bond is sufficiently strong so that the crystal is just as apt to break or cleave in other directions than along the CHI interface. This means that when cleaved or sawn, the interface will not have a preference to have the crystal delaminate or break at the interface. Another characteristic of the CHI interface strength is the ability to withstand high-temperature anneals without delaminating, specifically from 500° C. to 700° C. at a minimum. Any of these aforementioned characteristics for CHI interface can be present alone or in combination.

As used herein, Band-Engineering and Glue (BEG) layers are layers that (i) improve wafer bonding characteristics while (ii) simultaneously maintaining or improving device performance without the BEG layer. Wafer bonding characteristics include at least one of: resistance at the wafer bond, defect density at the wafer bond, voids at the wafer bond, and strength of the wafer bonded interface. Device characteristics include resistance, band offset, and carrier transport across the interface. Preferably, BEG layers may contain In-bearing III-V materials as well as any material with enhanced mass transport or solid-state regrowth speed and bond strength. For the III-N layers, this may include InₓGa₁₋ₓN, or InAlGaN. In the case of InₓGa₁₋ₓN, x=0 to 0.5, preferably 0 to 0.3. For the III-As/P/Sb materials, BEG layers can include InGaAs, InGaP, GaAsSb. In general, BEG layers should be low-defect density, and hence lattice matched to the native growth substrate. They also may be pseudomorphic or if needed strained or partially strained/relaxed, or relaxed. The BEG layers can comprise multiple layers, with the most important layer relative to the wafer bonding characteristic properties being the layers adjacent to the wafer bonding interface. It is the adjacent layers that should have the improved wafer bonding characteristics. In general, in order to minimize defects, BEG layers should be grown on similar or lattice-matched native substrates (e.g., III-N BEG layers grown on GaN or AlN, III-As/P/Sb BEG layers grown on InP, GaAs, or GaSb).

As used herein, “lattice-matched” means having the same or nominally the same lattice constant as the substrate upon which they are grown. Imperfect but sufficient lattice-matching can still provide high-quality crystal layers for thickness typically needed in devices. Lattice-matching is defined as the change in lattice constant from the heteroepitaxial layer and the substrate (a_{layer}-a_{substrate}) divided by the lattice constant of the substrate (a_{substrate}), where a is the lattice constant of a given material. The lattice mismatch is defined as |(a_{layer}-a_{substrate})|/a_{substrate}, or |Da|/a. For purposes of this invention, sufficient lattice match (|Da|/a.) is <3% and preferably <2%, more preferably <1.5%, most preferably <1%. It should be noted that this is for thick layers. Pseudomorphic layers by definition can exceed these amounts as long as they are below the critical thickness (see, J. W. Matthews and A. E. Blakeslee, J. Cryst. Growth 27, 118 (1974)).

Described herein are alternative device structures that can give improved performance and are more technologically feasible. These devices use InP-based materials for the emitter-base and GaN-based collectors for a HBT. The collector layers are grown on low-defect bulk or free-standing GaN substrates (for reduced defect density).

The advantage of using InP is significant in that it has a coefficient of thermal expansion (CTE) that much more closely matches GaN (and AlN) compared to device structures using other materials, such as those shown in the table below.

| | α × 10⁻⁶, | Δ from | Δ from |
|---|---|---|---|
| Substrate | K⁻¹ (at 600° C.) | GaAs (%) | InP (%) |
| GaAs | 7.3 | — | — |
| Al₂O₃ | 7.8 | 7% | 57% |
| GaN | 5.1 | −30% | 2% |
| AlN | 4.9 | −33% | −2% |
| InP | 5.0 | — | — |

The large CTE mismatch between GaAs substrates and GaN substrates (or AlN substrates) results in significant wafer bonding problems (e.g., weak bonds, large non-bonded regions, need to minimize wafer bonding temperature and ramp rate). The small CTE mismatch between InP and GaN and AlN enables the bonding of InP and InP-based films to GaN and AlN (and III-N epi grown upon them). With this, repeatable large bonded areas (>95%) with strong bonds (able to survive sawing and cleaving) have been achieved. Further, samples were able to be wafer bonded over a wide temperature range (e.g., >550-800° C.).

In FIG. 11, the sample is GaAs bonded to free-standing GaN. The large lattice mismatch results in large non-bonded areas and generally weaker bonds. In contrast, an InP wafer bonded to free-standing GaN shows ˜100% bonded area and a strong robust mechanical interface (FIG. 12).

Thus, a significant improvement results from the use of InP-based materials (on InP substrates) wafer bonded to GaN or GaN-based materials or AlN or AlN based materials on bulk or free standing GaN or AlN substrates for wafer bonding. This can be of potential significant benefit for high-yield and high-performance manufacturing of HBTs.

The table below provides material properties for GaAs, In_{0.53}Ga_{0.47}As, InP GaN, Al_{0.7}Ga_{0.3}N, and AlN [Gao et al. 1991, Tsao et al. 2018]. These properties are used herein as examples to illustrate the advantageous properties of each material. For example, it can be seen that InGaAs offers the highest electron and hole mobilities amongst the materials considered here, making it an attractive candidate for the base layer, whereas AlₓGa₁₋ₓN (x=0 to 1) offers the highest critical electric field, making it attractive for the collector layer. This is further explored below.

| | μₙ | μₚ | | E_{c} | v_{SAT} |
|---|---|---|---|---|---|
| Material | [cm²/V · s)] | [cm²/V · s)] | εₛ | [MV/cm] | [×10⁷ cm/s] |
| GaAs | 1200 | 60 | 13.1 | 0.47 | 0.83 |
| In_{0.53}Ga_{0.47}As | 1500 | 100 | 13.77 | n/a | n/a |
| InP | 1000 | 30 | 12.35 | 0.43 | 1.1 |
| GaN | 1000 | 20 | 10.4 | 3.5 | 1.4 |
| Al_{0.7}Ga_{0.3}N | 200 | — | 8.8 | 10 | 1.0 |
| AlN | 400 | — | 8.5 | 15 | 1.3 |

These properties can be used to estimate the performance of an HBT using the following relationships describe figures of merit (FOM) for the base and collector regions:

$$\begin{matrix}{FOM}_{b a s e} = {( \frac{{μ}_{nB}^{1 / 2} {μ}_{p B} {N}_{B}}{{ε}_{r} {ε}_{0}} )}^{1 / 2} \\ {FOM}_{C o l l e c t o r} = {v}_{d}^{5 / 4} {W}_{c}^{5 / 4} {E}_{c} {N}_{c} \\ {FOM}_{H B T} = {FOM}_{B a s e} \times {FOM}_{C o l l e c t o r}\end{matrix}$$

Using these equations and abovementioned material properties, the performance of heterogeneously integrated HBTs is compared in the table below. Note that all FOMs are referenced to the GaAs/GaAs B-C case.

| Base | Collector | Base FOM | Collector FOM | HBT FOM |
|---|---|---|---|---|
| GaAs | GaAs | 1 | 1 | 1 |
| In_{0.53}Ga_{0.47}As | InP | 1.3 | 1.3 | 1.7 |
| GaN | GaN | 0.6 | 14.3 | 8.9 |
| GaAs | GaN | 1 | 14.3 | 14.3 |
| In_{0.53}Ga_{0.47}As | GaN | 1.3 | 14.3 | 18.6 |
| GaAs | Al_{0.7}Ga_{0.3}N | 1 | 26.9 | 26.9 |
| In_{0.53}Ga_{0.47}As | Al_{0.7}Ga_{0.3}N | 1.3 | 26.9 | 35 |

As can be seen, the base's FOM can be maximized by using GaAs on GaAs substrates and In_{0.53}Ga_{0.47}As on InP substrates because these materials have superior hole mobility. The GaAs and InP growth substrates respectively are important to the lattice-matched heteroepitaxy of the GaAs and In_{0.53}Ga_{0.47}As layers and the realization of sufficient material quality for device applications. This is in contrast to the relatively low hole mobility achievable in p-type GaN, if used for the base region. While not captured in this table, the ability to make low resistance contacts to p-type GaAs and In_{0.53}Ga_{0.47}As is another benefit to using these materials, as is the lower ionization energy of acceptor dopants, which increases the carrier concentration and reduces base resistance. The collector's FOM, on the other hand, is maximized by adopting materials with a wide bandgap. This is where the large critical electric field and saturation velocities of wide bandgap GaN and ultra-wide bandgap Al_{0.7}Ga_{0.3}N can be most effectively exploited to provide high power performance.

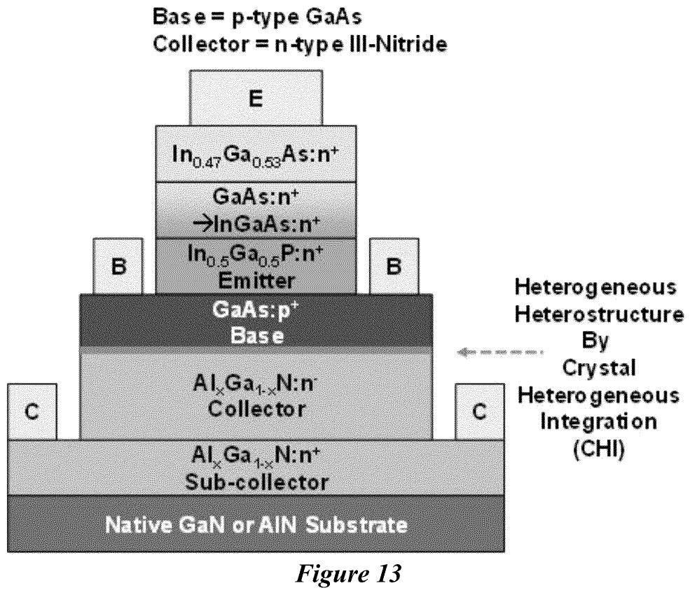

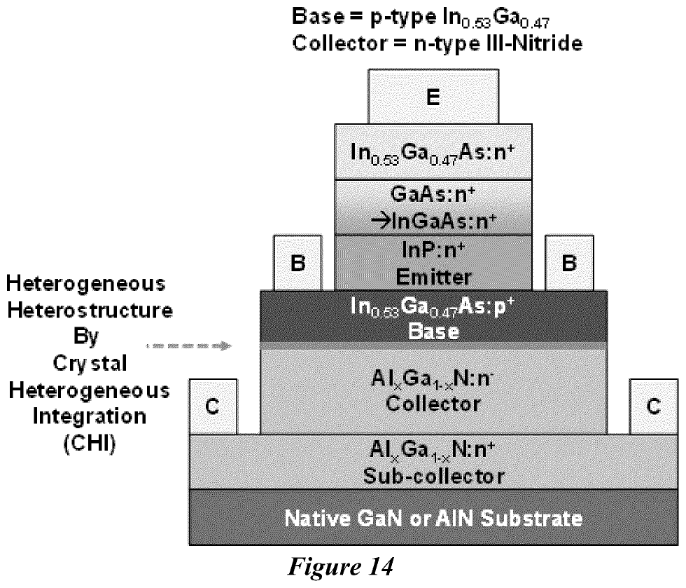

The last four rows of the table include the four material combinations that have the most promise. Unfortunately, these materials cannot be realized by heteroepitaxy due to the large lattice mismatch as well as the different crystal structure between the III-N and the III-As or III-Players (III-Nitrides are generally grown as wurtzite crystals wherein III-As, III-P, III-Sb, or III-AsPSb are zinc blende structures). Thus, workers in the field have turned to wafer-bonding to integrate these disparate materials. The GaAs/GaN case has been investigated by others by standard wafer bonding techniques, but not with the BEG and CHI methods of making proposed herein. Moreover, past examples of GaAs/GaN junctions have used GaN thin films grown on foreign substrates, such as sapphire, which increases the dislocation density in the films, in turn compromising the critical electric field, and introduces a larger thermal resistance that limits the HBT's high power performance. On the other hand, B-C(base-collector) junctions comprising In_{0.53}Ga_{0.47}As (on InP)/GaN (on GaN) or In_{0.53}Ga_{0.47}As (on InP)/Al_{0.7}Ga_{0.3}N (on GaN) have not been investigated by others thus far. The In_{0.53}Ga_{0.47}As/GaN and In_{0.53}Ga_{0.47}As/Al_{0.7}Ga_{0.3}N cases, in particular, addresses the CTE mismatch challenge addressed above, and are therefore very attractive. In all three cases, these solutions provide at least a 10× performance improvement over state-of-the-art InP/InGaAs HBTs. Thus, the structures shown in FIG. 13 and FIG. 14 are proposed herein.

FIG. 13 describes an HBT where InGaP/GaAs are used for the Emitter/Base layers, and integrated with a (U)WBG GaN/AlGaN collector. An InGaP to InGaAs transition layer and InGaAs layer are added to facilitate low resistance contacts to the Emitter region. In this embodiment, the InGaP/GaAs layers would be lattice-matched and grown on a GaAs substrate. Thus, In_{0.5}Ga_{0.5}P and In_{0.47}Ga_{0.53}As are preferred. AlGaAs/GaAs could also be used as an Emitter/Base combination.

As explained above, the large CTE mismatch between GaAs and GaN or AlN substrates makes wafer fusion challenging. Thus, FIG. 14 describes the HBT structure where InP and GaN or AlN substrates are used. InP/In_{0.53}Ga_{0.47}As are used for the Emitter/Base layers, and integrated with a (U)WBG GaN/AlGaN collector. An InP to InGaAs transition layer and InGaAs layer are added to facilitate low resistance contacts to the Emitter region. In this embodiment, the InP/InGaAs layers would be lattice-matched and grown on an InP substrate. Thus, In_{0.52}Ga_{0.47}As is preferred.

Based on this, the following are additional methods, devices, and/or uses are proposed herein:
Use III-AsPSb alloys grown on InP to better match CTE of bulk GaN or AlN substrates
Use of high-yield, low-defect density wafer bonding utilizing GaN or AlN bulk substrates
InP-InGaAs-GaN HBT
InP-InGaAs-AlGaN HBT
Use GaAsSb base alternative to an In_{0.53}Ga_{0.47}As base
Use of Band-Engineering and Glue Semiconductor Layers at III-N or III-As/P Interface at base-collector. This includes adding thin (<5 nm thick), doped or undoped, (In)GaAs or GaAsSb layers to the second substrate's epitaxial structure prior to bonding, or adding thin (<5 nm thick), doped or undoped, InGaN layers to the first substrate's epitaxial structure prior to bonding. This includes the use of spike or delta doping at the B-C interface.
Use of Crystal Heterogeneous Integration (CHI) for Wafer Fusion
Use metal-polar or nitrogen-polar orientations of GaN, AlGaN or AlN in order to manage polarization fields and reduce the conduction band discontinuity for enhanced carrier transport at the B-C junction

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The methods of the appended claims are not limited in scope by the specific methods described herein, which are intended as illustrations of a few aspects of the claims and any methods that are functionally equivalent are intended to fall within the scope of the claims. Various modifications of the methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

What is claimed is:

1. A method of making a heterogeneous heterojunction bipolar transistor (HBT) device, the method comprising:
depositing a collector layer on a first substrate;
depositing an emitter layer on a second substrate and subsequently depositing a base layer on the emitter layer;
fusing the base layer to the collector layer using crystal heterogeneous integration wafer bonding, thereby forming an interface that fuses the base layer to the collector layer and thus forming a precursor device comprising:
the first substrate, the collector layer, the interface, the base layer, the emitter layer, and the second substrate; wherein:
the collector layer is disposed on top of and in physical contact with the first substrate;
the interface is disposed on top of and in physical contact with the collector layer, such that the collector layer is disposed between and in physical contact with the first substrate and the interface;
the base layer is disposed on top of and in physical contact with the interface, such that the interface is disposed between and in physical contact with the collector layer and the base layer;
the emitter layer is disposed on top of and in physical contact with the base layer, such that the base layer is disposed between and in physical contact with the interface and the emitter layer; and
the second substrate is disposed on top of an in physical contact with the emitter layer, such that the emitter layer is disposed between and in physical contact with the base layer and the second substrate;
and
processing the precursor device to remove the second substrate, thereby forming the heterogeneous heterojunction bipolar transistor (HBT) device;
wherein the first substrate comprises Al_{w}Ga_{1-w}N where w is from 0 to 1, Si, sapphire, SiC, or a combination thereof;
wherein the second substrate comprises an InP-based material;
wherein:
the first substrate and the collector layer have a lattice mismatch of 30% or less;
the second substrate and the emitter layer have a lattice mismatch of 30% or less;
wherein:
the collector layer has a first band gap, the emitter layer has a second bandgap, and the base layer has a third bandgap;
the first bandgap is greater than the third bandgap; and
the second band gap is greater than the third bandgap;
wherein:
the first substrate has a first coefficient of thermal expansion; and
the second substrate has a third coefficient of thermal expansion;
wherein the difference between the first coefficient of thermal expansion and the third coefficient of thermal expansion is 30% or less.

2. The method of claim 1, wherein fusing the base layer to the collector layer using crystal heterogeneous integration wafer bonding, comprises:
contacting the base layer with the collector layer at a first elevated temperature and at an elevated pressure in an environment with an overpressure of a gas comprising a group V element or compound; and
subsequently applying a uniaxial force to the first substrate and/or the second substrate for an amount of time, and optionally at a second elevated temperature, wherein the force is applied in a direction that is substantially perpendicular to a plane substantially parallel with the first substrate and/or the second substrate.

3. The method of claim 2, wherein the first elevated temperature is from 400 to 1000° C., the elevated pressure is from 1 MPa to 100 MPa, or a combination thereof.

4. The method of claim 2, wherein the uniaxial force is from 1 to 100 MPa, the amount of time the uniaxial force is applied is from 1 second to 24 hours, the second elevated temperature is from 400 to 1000° C., or a combination thereof.

5. The method of claim 2, wherein the group V element or compound comprises a nitrogen compound, a phosphorous compound, an arsenic compound, or a combination thereof.

6. The method of claim 1, wherein the first substrate comprises Al_{w}Ga_{1-w}N where w is from 0 to 1.

7. The method of claim 1, wherein the collector layer comprises AlₓGa₁₋ₓN, wherein x is from 0 to 1.

8. The method of claim 1, wherein the first substrate comprises GaN and the collector layer comprises AlₓGa₁₋ₓN, wherein x is from 0 to 0.5.

9. The method of claim 1, wherein the first substrate comprises AlN and the collector layer comprises AlₓGa₁₋ₓN, wherein x is from 0.5 to 1.

10. The method of claim 1, wherein the base layer comprises In_{y}Ga_{1-y}As, wherein y is from 0 to 1, or wherein the base layer comprises GaAsₐSb₁₋ₐ, wherein a is from 0 to 1.

11. The method of claim 1, wherein the base layer comprises In_{0.53}Ga_{0.47}As, GaAs, InAlGaAs, InGaAsP, or a combination thereof.

12. The method of claim 1, wherein the base layer comprises In_{y}Ga_{1-y}As and the collector layer comprises AlₓGa₁₋ₓN.

13. The method of claim 1, wherein the emitter layer comprises InP, InAlGaAs, InAlAs, InGaAsP, or a combination thereof.

14. The method of claim 1, wherein the collector layer comprises an n-type material, the base layer comprises a p-type material, and the emitter layer comprises an n-type material, such that the heterogeneous heterojunction bipolar transistor (HBT) device has an NPN structure; or wherein the collector layer comprises a p-type material, the base layer comprises an n-type material, and the emitter layer comprises a p-type material, such that the heterogeneous heterojunction bipolar transistor (HBT) device has a PNP structure.

15. The method of claim 1, wherein the method further comprises depositing a release layer on the second substrate, subsequently depositing the emitter layer on the release layer, and subsequently depositing the base layer on the emitter layer, such that the precursor device further comprises the release layer wherein the release layer disposed on top of an in physical contact with the emitter layer, such that the emitter layer is disposed between and in physical contact with the base layer and the release layer, and the second substrate is disposed on top of an in physical contact with the release layer, such that the release layer is disposed between and in physical contact with the emitter layer and the second substrate.

16. The method of claim 1, wherein the collector layer comprises a first collector layer and a second collector layer, and the method comprises depositing the first collector layer on the first substrate and subsequently depositing the second collector layer on the first collector layer, such that in the precursor device the first collector layer is disposed on and in physical contact with the first substrate, and the second collector layer is disposed on and in physical contact with the first collector layer, such that the first collector layer is disposed between and in physical contact with the first substrate and the second collector layer.

17. The method of claim 1, further comprising depositing one or more additional layers on the second substrate before depositing the emitter layer, such that the precursor device further comprises the one or more additional layers, which are disposed between and in physical contact with the emitter layer and the second substrate.

18. The method of claim 1, further comprising depositing a first contact comprising a first metal on at least a portion of the collector layer, depositing a second contact comprising a second metal on at least a portion of the base layer, depositing a third contact comprising a third metal on at least a portion of the emitter layer, or a combination thereof.

19. A heterogeneous heterojunction bipolar transistor (HBT) device made by the method of claim 1.

20. A heterogeneous heterojunction bipolar transistor (HBT) device comprising:
a first substrate, a collector layer, an interface, a base layer, and an emitter layer, wherein:
the collector layer is disposed on top of and in physical contact with the first substrate;
the interface is disposed on top of and in physical contact with the collector layer, such that the collector layer is disposed between and in physical contact with the first substrate and the interface;
the base layer is disposed on top of and in physical contact with the interface, such that the interface is disposed between and in physical contact with the collector layer and the base layer;
the emitter layer is disposed on top of and in physical contact with the base layer, such that the base layer is disposed between and in physical contact with the interface and the emitter layer; and
wherein the first substrate comprises Al_{w}Ga_{1-w}N where w is from 0 to 1;
wherein the collector layer is epitaxially grown on the first substrate;
wherein the collector layer comprises a group III-nitride based material;
wherein:
the emitter layer has a lattice-constant and/or a crystal structure that is different than that of the base layer and/or the collector layer;
wherein the emitter layer and the base layer have a lattice constant that is lattice-matched to InP;
wherein:
the collector layer has a first band gap, the emitter layer has a second bandgap, and the base layer has a third bandgap;
the first bandgap is greater than the third; and
the second band gap is greater than the third bandgap.
